(19) United States
(12) Patent Application Publication
(10) Pub. No.: US 2023/0255037 A1
(43) Pub. Date: Aug. 10, 2023

(54) THREE-DIMENSIONAL NON-VOLATILE MEMORY DEVICE INCLUDING PERIPHERAL CIRCUITS

(71) Applicant: SAMSUNG ELECTRONICS CO., LTD., Suwon-si (KR)

(72) Inventors: Beakhyung CHO, Suwon-si (KR); Daeseok BYEON, Suwon-si (KR)

(73) Assignee: SAMSUNG ELECTRONICS CO., LTD., Suwon-si (KR)

(21) Appl. No.: 18/095,147

(22) Filed: Jan. 10, 2023

(30) Foreign Application Priority Data
Feb. 4, 2022 (KR) 10-2022-0015073
Jun. 30, 2022 (KR) 10-2022-0080715

(51) Int. Cl. H10B 80/00

(52) U.S. Cl. CPC H10B 80/00

(57) ABSTRACT

In some embodiments, a non-volatile memory device includes a first semiconductor chip and a second semiconductor chip. The first semiconductor chip includes gate electrodes, channel structures, a plurality of cell contact plugs, a linear metal pattern, and a plurality of upper bonding pads. The second semiconductor chip includes a plurality of lower bonding pads, a first peripheral circuit element overlapping the channel structures, a second peripheral circuit element overlapping the plurality of cell contact plugs, and a third peripheral circuit element overlapping the plurality of cell contact plugs. The peripheral circuit elements are coupled to corresponding cell contact plugs. Widths in the first direction of the second upper bonding pad and the third upper bonding pad are different from each other, and widths in the first direction of the second lower bonding pad and the third lower bonding pad are different from each other.

### CROSS-REFERENCE TO RELATED APPLICATIONS

This application claims priority to Korean Patent Application No. 10-2022-0015073, filed on Feb. 4, 2022, and Korean Patent Application No. 10-2022-0080715, filed on Jun. 30, 2022, in the Korean Intellectual Property Office, the disclosures of which are incorporated by reference herein in their entireties.

### BACKGROUND

### 1. Field

The present disclosure relates to a memory device, and more particularly, to a three-dimensional (3D) non-volatile memory device in which a first semiconductor chip having memory cells arranged therein and a second semiconductor chip having peripheral circuits arranged therein are connected to one another in a bonding manner.

### 2. Description of Related Art

Related memory devices may be used to store data and may include volatile memory devices and non-volatile memory devices. As high-capacitance and miniaturization of non-volatile memory devices are required, related 3D memory devices, in which a memory cell array is arranged in a direction perpendicular to a peripheral circuit, have been developed. Examples of 3D memory devices may include chip to chip (C2C) memory devices in which a first semiconductor chip having memory cells arranged therein and a second semiconductor chip having peripheral circuits arranged therein are connected to one another in a bonding manner. In the case of a C2C memory device, as the number of word lines arranged on the first semiconductor chip increases, the number of pass transistors corresponding to the word lines may also increase. Thus, the number of metal layers for connection between the word lines and the pass transistors or wiring complexity may increase, which may result in an increase in the size of the C2C memory device and a manufacturing cost thereof.

### SUMMARY

The present disclosure provides a non-volatile memory device in which the number of metal layers for wiring connection within a chip to chip (C2C) memory device and wiring complexity are reduced so that the size of the C2C memory device and a manufacturing cost thereof may decrease.

According to an aspect of the present disclosure, a non-volatile memory device is provided. The non-volatile memory device includes a first semiconductor chip and a second semiconductor chip. The first semiconductor chip includes gate electrodes each extending in a first direction and stacked in a second direction, channel structures extending from a first region in the second direction, a plurality of cell contact plugs, a linear metal pattern extending in the first direction, and a plurality of upper bonding pads including a first upper bonding pad, a second upper bonding pad, and a third upper bonding pad. The plurality of cell contact plugs include a first cell contact plug, a second cell contact plug, and a third cell contact plug. Each cell contact plug of the plurality of cell contact plugs is coupled to the gate electrodes in a second region. The second semiconductor chip includes a plurality of lower bonding pads, a first peripheral circuit element overlapping the channel structures, a second peripheral circuit element overlapping the plurality of cell contact plugs, and a third peripheral circuit element overlapping the plurality of cell contact plugs. The plurality of lower bonding pads include a first lower bonding pad, a second lower bonding pad, and a third lower bonding pad. The first cell contact plug is coupled to the first peripheral circuit element through the linear metal pattern, the first upper bonding pad, and the first lower bonding pad. The second cell contact plug is coupled to the second peripheral circuit element through the second upper bonding pad and the second lower bonding pad. The third cell contact plug is coupled to the third peripheral circuit element through the third upper bonding pad and the third lower bonding pad. A width in the first direction of the second upper bonding pad is different from a width in the first direction of the third upper bonding pad. A width in the first direction of the second lower bonding pad is different from a width in the first direction of the third lower bonding pad.

According to an aspect of the present disclosure, a non-volatile memory device is provided. The non-volatile memory device includes a first semiconductor chip and a second semiconductor chip. The first semiconductor chip includes gate electrodes each extending in a first direction and stacked in a second direction, channel structures extending from a first region in the second direction, cell contact plugs each coupled to the gate electrodes in a second region, a first upper bonding pad, and a second upper bonding pad. The second semiconductor chip includes a first lower bonding pad, a second lower bonding pad, a first peripheral circuit element overlapping the channel structures, and a second peripheral circuit element overlapping the cell contact plugs. A first cell contact plug of the cell contact plugs is coupled to the first peripheral circuit element through the first upper bonding pad and the first lower bonding pad. A second cell contact plug of the cell contact plugs is coupled to the second peripheral circuit element through the second upper bonding pad and the second lower bonding pad. The second upper bonding pad and the second lower bonding pad have a first width in the first direction. At least one of the first upper bonding pad and the first lower bonding pad has a second width in the first direction greater than the first width.

According to an aspect of the present disclosure, a non-volatile memory device is provided. The non-volatile memory device includes a first semiconductor chip and a second semiconductor chip. The first semiconductor chip includes a memory cell array, a first upper bonding pad having a first width in a first direction, and a second upper bonding pad having a second width greater in the first direction than the first width. The second semiconductor chip includes a first lower bonding pad and coupled to the first semiconductor chip in a vertical direction through the first upper bonding pad and the first lower bonding pad. The second semiconductor chip further includes a second lower bonding pad coupled to the second upper bonding pad, a third lower bonding pad coupled to the second upper bonding pad, a first peripheral circuit element coupled to the second lower bonding pad, and a second peripheral circuit element coupled to the third lower bonding pad. The first peripheral circuit element is coupled to the second peripheral circuit element through the second lower bonding pad, the second upper bonding pad, and the third lower bonding pad.

### BRIEF DESCRIPTION OF DRAWINGS

The above and other aspects, features, and advantages of certain embodiments of the present disclosure will be more apparent from the following description taken in conjunction with the accompanying drawings in which:

FIG. 1 is a block diagram illustrating a memory device, according to an embodiment;

FIG. 2 is a circuit diagram illustrating a memory block, according to an embodiment;

FIGS. 3A and 3B are perspective views illustrating memory blocks, according to some embodiments;

FIG. 4 illustrates a memory device having a bonding vertical NAND (B-VNAND) structure, according to an embodiment;

FIG. 5 illustrates a memory device, according to an embodiment;

FIG. 6 illustrates a memory device, according to an embodiment;

FIG. 7 is a cross-sectional view illustrating a memory device, according to an embodiment;

FIG. 8 illustrates a memory device, according to an embodiment;

FIG. 9 is a cross-sectional view illustrating a memory device according to an embodiment;

FIG. 10 illustrates a memory device, according to an embodiment;

FIG. 11 is a cross-sectional view illustrating a memory device, according to an embodiment;

FIG. 12 illustrates a memory device, according to an embodiment;

FIGS. 13 through 15 are cross-sectional views illustrating memory devices, according to some embodiments;

FIG. 16 illustrates a memory device, according to an embodiment;

FIG. 17 is a cross-sectional view illustrating a memory device, according to an embodiment;

FIG. 18 illustrates a memory device, according to an embodiment;

FIG. 19 is a cross-sectional view illustrating a memory device, according to an embodiment;

FIG. 20 illustrates a memory device, according to an embodiment;

FIG. 21 is a cross-sectional view illustrating a memory device, according to an embodiment;

FIG. 22 illustrates a memory device, according to an embodiment;

FIG. 23 is a cross-sectional view illustrating a memory device, according to an embodiment;

FIG. 24 illustrates a memory device, according to an embodiment;

FIG. 25 is a cross-sectional view illustrating a memory device, according to an embodiment;

FIG. 26 illustrates a memory device, according to an embodiment;

FIG. 27 is a cross-sectional view illustrating a memory device, according to an embodiment;

FIG. 28 is a cross-sectional view of a memory device having a B-VNAND structure, according to an embodiment; and

FIG. 29 is a block diagram illustrating a solid state drive (SSD) system to which a memory device, according to an embodiment is applied.

### DETAILED DESCRIPTION

The following description with reference to the accompanying drawings is provided to assist in a comprehensive understanding of embodiments of the present disclosure defined by the claims and their equivalents. The embodiments described herein are example embodiments. Various specific details are included to assist in understanding, but these details are considered to be examples only. Therefore, those of ordinary skill in the art will recognize that various changes and modifications of the embodiments described herein can be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

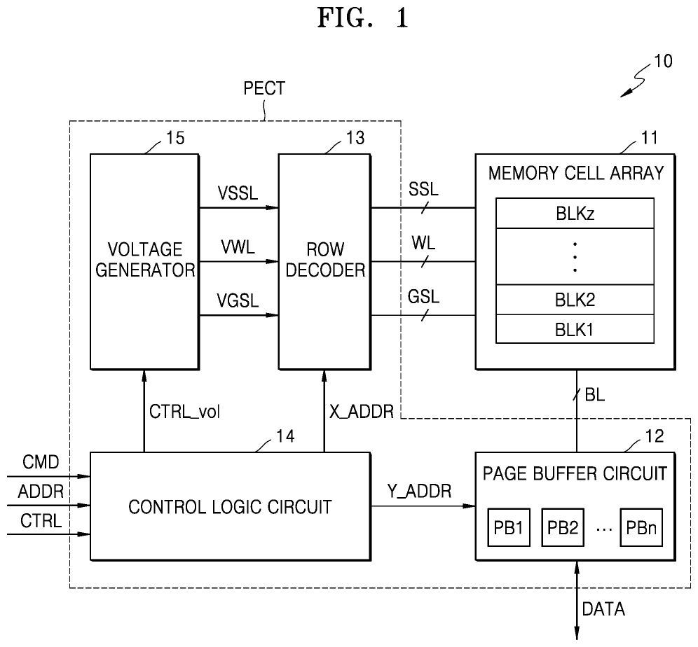

FIG. 1 is a block diagram illustrating a memory device according to an embodiment.

Referring to FIG. 1, a memory device 10 may include a memory cell array 11 and a peripheral circuit PECT, and the peripheral circuit PECT may include a page buffer circuit 12, a row decoder 13, a control logic circuit 14, and a voltage generator 15. In some embodiments, the peripheral circuit PECT may further include a data input/output circuit, an input/output interface, or the like (not shown). Alternatively or additionally, the peripheral circuit PECT may further include a pre-decoder, a temperature sensor, a command decoder, an address decoder, and the like. In the present disclosure, the memory device 10 may be referred to as a non-volatile memory device.

The memory cell array 11 may include a plurality of memory blocks BLK1 through BLKz (hereinafter “BLK”, generally), where z is a positive integer. Each of the plurality of memory blocks BLK may include a plurality of memory cells. The memory cell array 11 may be connected to the page buffer circuit 12 through bit lines BL and may be connected to the row decoder 13 through word lines WL, string selection lines SSL, and ground selection lines GSL. For example, the memory cells may include flash memory cells. Hereinafter, embodiments of the present disclosure are described with reference to a case where the memory cells are NAND flash memory cells. However, embodiments are not limited thereto. For example, in some embodiments, the memory cells may be resistive memory cells, such as resistive RAM (ReRAM) memory cells, phase change RAM (PRAM) memory cells, or magnetic RAM (MRAM) memory cells.

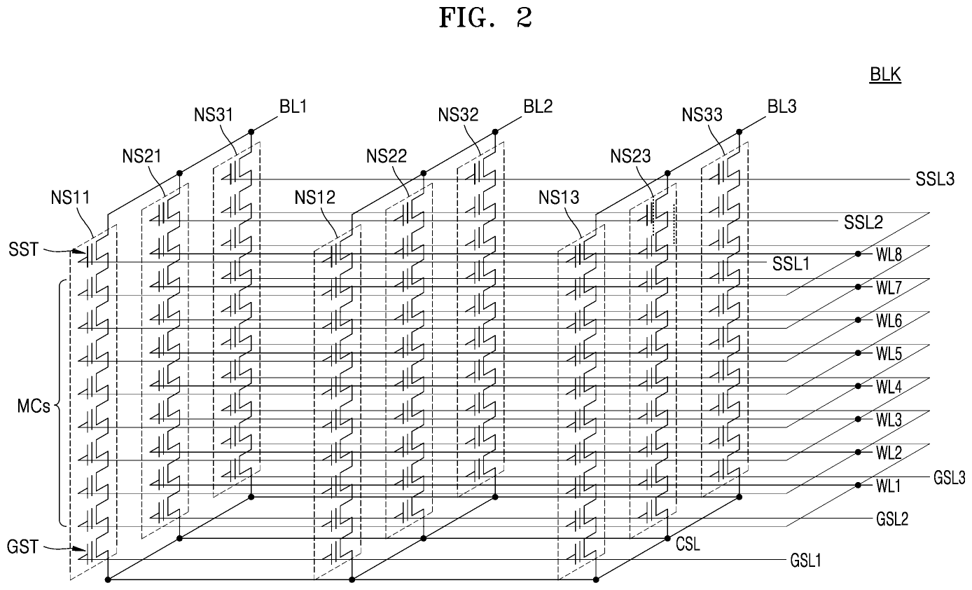

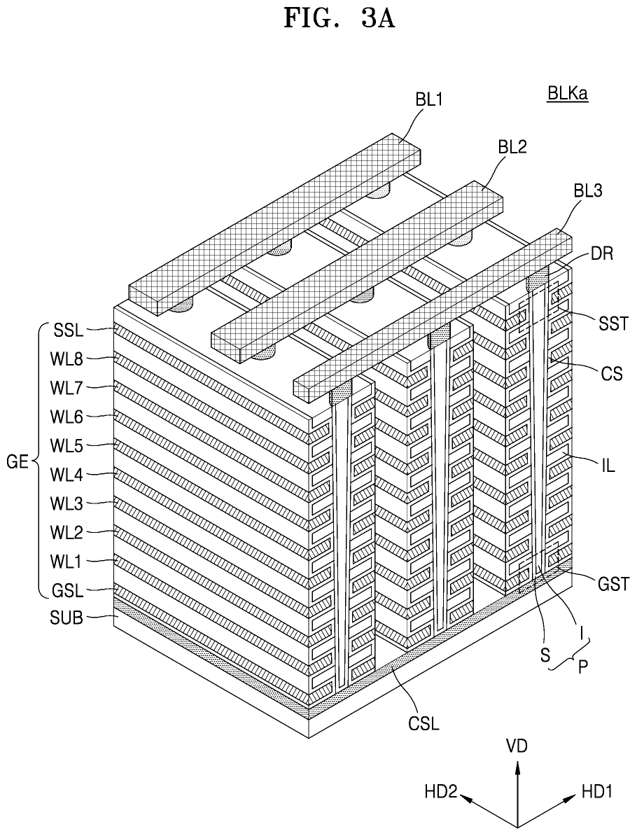

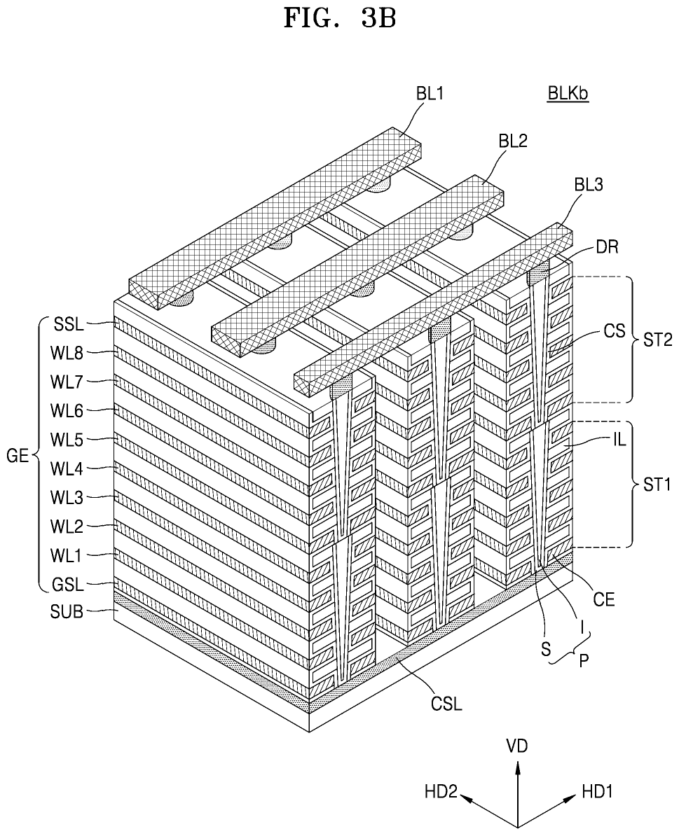

In some embodiments, the memory cell array 11 may include a three-dimensional (3D) memory cell array, and the 3D memory cell array may include a plurality of NAND strings, and each of the plurality of NAND strings may include memory cells respectively connected to word lines stacked on a substrate in a vertical direction, as described with reference to FIGS. 2 through 3B. U.S. Pat. Nos. 7,679,133, 8,553,466, 8,654,587, 8,559,235, and U.S. Patent No. 2011/0233648, the disclosures of which are incorporated by reference herein in their entireties, disclose configurations for a 3D memory array in which the 3D memory array includes a plurality of levels and word lines and/or bit lines are shared between the plurality of levels. However, embodiments are not limited thereto. For example, in some embodiments, the memory cell array 11 may include a two-dimensional (2D) memory cell array, and the 2D memory cell array may include a plurality of NAND strings arranged in row and column directions.

The page buffer circuit 12 may include a plurality of page buffers PB1 through PBn (hereinafter “PB”, generally), where n is a positive integer. Each of the plurality of page buffers PB may be connected (coupled) to memory cells of the memory cell array 11 through each of bit lines corresponding to each of the plurality of page buffers PB. The page buffer circuit 12 may select at least one bit line among the bit lines BL according to control of the control logic circuit 14. For example, the page buffer circuit 12 may select some bit lines of the bit lines BL in response to a column address Y_ADDR received from the control logic circuit 14.

Each of the plurality of page buffers PB may operate as a write driver or sense amplifier. For example, in a programming operation, each of the plurality of page buffers PB may apply a voltage corresponding to data to be programmed to the bit lines to store the data in the memory cell. As another example, in a program verification operation or reading operation, each of the plurality of page buffers PB may sense a current or voltage through the bit lines to sense the programmed data.

The control logic circuit 14 may output various control signals for programming data into the memory cell array 11, reading data from the memory cell array 11, or erasing data stored in the memory cell array 11, for example, a voltage control signal CTRL_vol, a row address X_ADDR, and a column address Y_ADDR. Thus, the control logic circuit 14 may control various operations in the memory device 10 generally. For example, the control logic circuit 14 may receive a command CMD, an address ADDR, and a control signal CTRL from a memory controller.

The voltage generator 15 may generate various types of voltages for performing programming, reading and erasing operations on the memory cell array 11 based on the voltage control signal CTRL_vol. For example, the voltage generator 15 may generate a word line voltage VWL, such as, but not limited to, a program voltage, a read voltage, a pass voltage, an erasing verification voltage or a program verification voltage. Alternatively or additionally, the voltage generator 15 may further generate a string selection line voltage VSSL and a ground selection line voltage VGSL, based on the voltage control signal CTRL_vol.

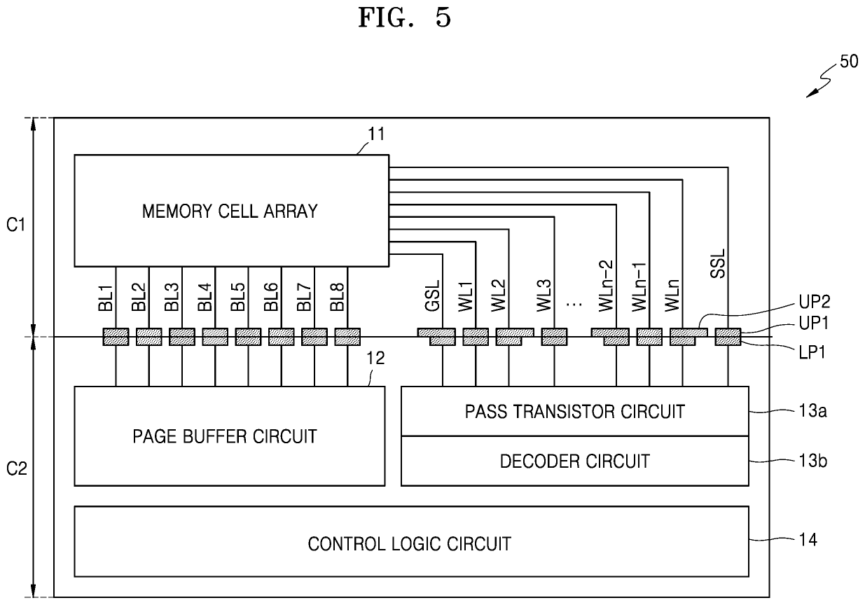

The row decoder 13 may select one of a plurality of memory blocks BLK in response to the row address X_ADDR received from the control logic circuit 14, may select one of word lines WL of the selected memory block, and may select one of a plurality of string selection lines SSL. For example, during a programming operation, the row decoder 13 may apply a program voltage and a program verification voltage to the selected word line, and during a reading operation, the row decoder 13 may apply a reading voltage to the selected word line. For example, the row decoder 13 may include a pass transistor circuit (e.g., 13a of FIG. 5) and a decoder circuit (e.g., 13b of FIG. 5).

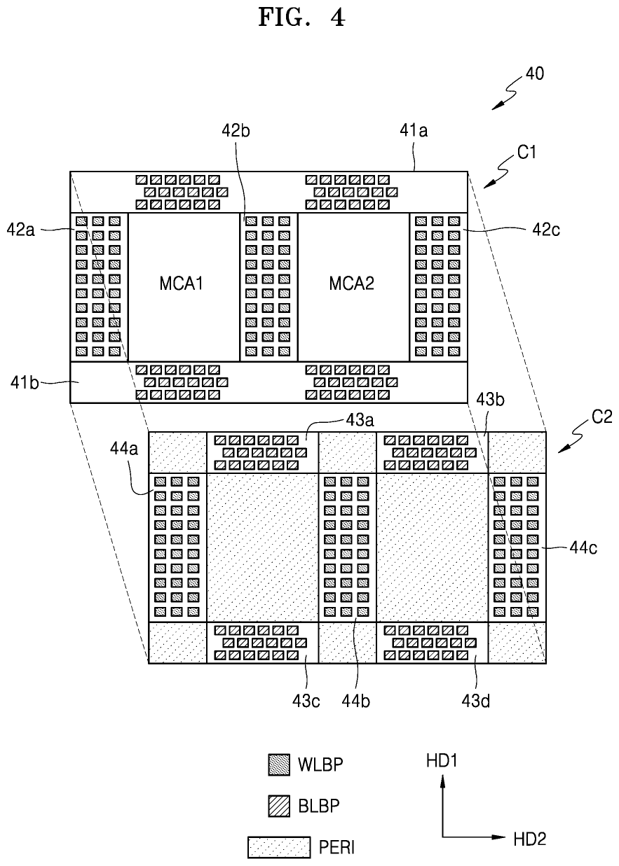

According to some embodiments, the memory cell array 11 may be arranged in a first semiconductor chip (e.g., C1 of FIG. 4), and a peripheral circuit PECT may be arranged in a second semiconductor chip (e.g., C2 of FIG. 4). The memory device 10 having this arrangement structure may be referred to as a bonding vertical NAND (B-VNAND)-type memory device or a memory device having a chip-to-chip (C2C) bonding structure. According to the C2C bonding structure, the horizontal area of the memory device 10 may be effectively reduced, and the degree of integration of the memory device 10 may be increased. According to some embodiments, the first semiconductor chip may be referred to as a first semiconductor layer, a first wafer, a first chip, a first die, an upper semiconductor layer, an upper wafer, an upper chip, an upper semiconductor chip or a cell region. According to some embodiments, the second semiconductor chip may be referred to as a second semiconductor layer, a second wafer, a second chip, a second die, a lower semiconductor layer, a lower wafer, a lower chip, a lower semiconductor chip or a peripheral region.

In some embodiments, the first semiconductor chip may include upper bonding pads connected to the memory cell array 11, the second semiconductor chip may include lower bonding pads connected to the peripheral circuit PECT, and the memory cell array 11 may be electrically connected to the peripheral circuit PECT through bonding between the upper bonding pads and the lower bonding pads. In this case, the word lines WL, the string selection lines SSL, the ground selection lines GSL, and the bit lines BL may be connected to the upper bonding pads and the lower bonding pads.

In some embodiments, the first semiconductor chip may be divided into a cell region or a first region in which memory cells are arranged and a stepped region or second region to which cell contact plugs respectively corresponding to gate electrodes are connected, and the second semiconductor chip may include first and second peripheral circuit elements. A first cell contact plug corresponding to a first gate electrode may be connected to a first peripheral circuit element arranged in a lower portion of the cell region through a first upper bonding pad and a first lower bonding pad, and a second cell contact plug corresponding to a second gate electrode may be connected to a second peripheral circuit element arranged in a lower portion of the stepped region through a second upper bonding pad and a second lower bonding pad. For example, the first and second peripheral circuit elements may be included in the row decoder 13. As another example, the width of the second upper bonding pad may be greater than the width of the first upper bonding pad. As another example, the width of the second lower bonding pad may be greater than the width of the first lower bonding pad. As another example, the widths of the first upper bonding pad and the first lower bonding pad may be substantially the same, and the widths of the second upper bonding pad and the second lower bonding pad may be greater than the widths of the first upper bonding pad and the first lower bonding pad.

In some embodiments, the first semiconductor chip may be classified into a cell region or a first region in memory cells and a stepped region or second region to which cell contact plugs respectively corresponding to gate electrodes are connected, and the second semiconductor chip may include first and second peripheral circuit elements. A first cell contact plug corresponding to a first gate electrode may be connected to the first peripheral circuit element arranged under the cell region through the first upper bonding pad and the first lower bonding pad, and a second cell contact plug corresponding to a second gate electrode may be connected to the second peripheral circuit element arranged under the stepped region through the second upper bonding pad and the second lower bonding pad. For example, the first and second peripheral circuit elements may be included in the row decoder 13. As another example, the width of the first upper bonding pad may be greater than the width of the second upper bonding pad. As another example, the width of the first lower bonding pad may be greater than the width of the second lower bonding pad. As another example, the widths of the first upper bonding pad and the first lower bonding pad may be greater than the widths of the second upper bonding pad and the second lower bonding pad.

In some embodiments, the first semiconductor chip may include a cell region in which bit lines BL are arranged, and the second semiconductor chip may include third and fourth peripheral circuit elements arranged under the cell region. A first bit line may be connected to a third peripheral circuit element through a third upper bonding pad and a third lower bonding pad, and a second bit line may be connected to a fourth peripheral circuit element through a fourth upper bonding pad and a fourth lower bonding pad. For example, the third and fourth peripheral circuit elements may be included in the page buffer circuit 12. As another example, the widths of the third and fourth upper bonding pads may be different from each other in a first direction. As another example, the widths of the third and fourth lower bonding pads may be different from each other in the first direction.

In some embodiments, the first semiconductor chip may include a memory cell array 11, and the second semiconductor chip may include first and second peripheral circuit elements. The first peripheral circuit element may be connected to the second peripheral circuit element through the first lower bonding pad, the upper bonding pad, and the second lower bonding pad. For example, the width of the upper bonding pad may be greater than the widths of the first lower bonding pad and the second lower bonding pad. As another example, the first and second peripheral circuit elements may be included in the row decoder 13, the control logic circuit 14, or the voltage generator 15.

FIG. 2 is a circuit diagram illustrating a memory block BLK according to an embodiment. Referring to FIG. 2, the memory block BLK may correspond to one of the plurality of memory blocks BLK of FIG. 1. The memory block BLK may include NAND strings NS11 to NS33, and each (e.g., NS11) of the NAND strings NS11 to NS33 may include a string selection transistor SST, a plurality of memory cells MCs, and a ground selection transistor GST, which are serially connected to one another. The string selection and ground selection transistors SST and GST and the memory cells MCs included in each NAND string may form a structure in which they are stacked on a substrate in a vertical direction.

First to third bit lines BL1 to BL3 may extend in a first direction or first horizontal direction, and word lines WL1 to WL8 may extend in a second direction or second horizontal direction. In the present disclosure, the first horizontal direction may indicate the first direction, and the second horizontal direction may indicate the second direction. The NAND strings NS11, NS21, and NS31 may be located between the first bit line BL1 and a common source line CSL, NAND strings NS12, NS22, and NS32 may be located between the second bit line BL2 and the common source line CSL, and NAND strings NS13, NS23, and NS33 may be located between the third bit line BL3 and the common source line CSL.

The string selection transistor SST may be connected to string selection lines SSL1 to SSL3 that correspond thereto. Each of the memory cells MCs may be respectively connected to word lines WL1 to WL8 that respectively correspond to the memory cells MCs. The ground selection transistor GST may be connected to ground selection lines GSL1 to GSL3 that correspond thereto. The string selection transistor SST may be connected to one of the bit lines corresponding to the string selection transistor SST, and the ground selection transistor GST may be connected to the common source line CSL. Here, the number of NAND strings, the number of word lines, the number of bit lines, the number of ground selection lines, and the number of string selection lines may be variously modified according to embodiments.

FIG. 3A is a perspective view illustrating a memory block BLKa according to an embodiment. Referring to FIG. 3A, the memory block BLKa may correspond to one of the plurality of memory blocks BLK of FIG. 1. The memory block BLKa may be formed in a vertical direction VD with respect to a substrate SUB. The substrate SUB may have a first conductivity type (e.g., a p-type) and may extend in a second direction or second horizontal direction HD2 on the substrate SUB. In some embodiments, the common source line CSL may be doped with impurities of a second conductivity type (e.g., a n-type) and thus may be provided onto the substrate SUB. In some embodiments, the common source line CSL may be implemented with a conductive layer, such as a metal layer. A plurality of insulating layers IL that extend in the second direction HD2 may be sequentially provided in the vertical direction VD, and the plurality of insulating layers IL may be spaced apart from each other by a certain distance in the vertical direction VD. For example, the plurality of insulating layers IL may include an insulating material, such as silicon oxide.

A plurality of pillars P that pass through the plurality of insulating layers IL in the vertical direction VD may be sequentially arranged in the first direction or the first horizontal direction HD1. For example, the plurality of pillars P may pass through the plurality of insulating layers IL and may be in contact with the substrate SUB. As another example, a surface layer S of each pillar P may include a silicon material having a first type and may function as a channel region. Thus, in some embodiments, the pillars P may be referred to as a channel structure or a vertical channel structure. An internal layer I of each pillar P may include an insulating material, such as silicon oxide or an air gap.

In the region between the two adjacent common source lines CSL, a charge storage layer CS may be provided along the exposed surface of the insulating layers IL, the pillars P, and the substrate SUB. The charge storage layer CS may include a gate insulating layer (or a tunneling insulating layer), a charge trapping layer, and a blocking insulating layer. In some embodiments, the charge storage layer CS may have an oxide-nitride-oxide (ONO) structure. Alternatively or additionally, in the region between the two adjacent common source lines CSL, a gate electrode GE, such as the ground and string selection lines GSL and SSL, and the word lines WL1 to WL8 may be provided on the exposed surface of the charge storage layer CS. Each of drain contacts (or drains) DR may be provided onto the plurality of pillars P. For example, the drains DR may include a silicon material doped with impurities having a second conductivity type. Bit lines BL1 to BL3 may be arranged on the drains DR and may extend in the first horizontal direction HD1 and may be spaced apart from each other in the second direction HD2 by a certain distance.

FIG. 3B is a perspective view illustrating a memory block BLKb according to an embodiment. Referring to FIG. 3B, the memory block BLKb may correspond to one of the plurality of memory blocks BLK of FIG. 1. The memory block BLKb may correspond to a modified example of the memory block BLKa of FIG. 3A, and, as such, descriptions given with reference to FIG. 3A may also be applied to the BLKb of FIG. 3B. The memory block BLKb may be formed in the vertical direction VD with respect to the substrate SUB. The memory block BLKb may include a first memory stack ST1 and a second memory stack ST2, which are stacked on each other in the vertical direction VD.

FIG. 4 illustrates a memory device 40 having a B-VNAND structure according to an embodiment. Referring to FIG. 4, the memory device 40 may include a first semiconductor chip C1 and a second semiconductor chip C2, and the first and second semiconductor chips C1 and C2 may be connected to each other in the vertical direction. In some embodiments, the first and second semiconductor chips C1 and C2 may be bonded to each other in a bonding manner. Thus, the memory device 40 may be referred to as a C2C memory device or a memory device having a C2C bonding structure.

The first semiconductor chip C1 may include a first memory cell array MCA1 and a second memory cell array MCA2. For example, each of the first and second memory cell arrays MCA1 and MCA2 may include NAND strings having a vertical structure. Thus, the memory device 40 may be referred to as a memory device having a B-VNAND structure. For example, the first and second memory cell arrays MCA1 and MCA2 may be arranged in the second direction HD2 to be adjacent to each other. In this case, the memory device 40 may be referred to as a memory device having a 2-MAT structure. In some embodiments, the memory device 40 may further include a memory cell array arranged adjacent to the first memory cell array MCA1 in the first direction HD1 and a memory cell array arranged adjacent to the second memory cell array MCA2 in the first direction HD1. In this case, the memory device 40 may be referred to as a memory device having a 4-MAT structure.

Alternatively or additionally, the first semiconductor chip C1 may further include bit line bonding regions 41a and 41b and word line bonding regions 42a, 42b, and 42c. Bit line bonding pads BLBP may be arranged in each of the bit line bonding regions 41a and 41b. The bit line bonding pads BLBP may be referred to as upper bit line bonding pads. Word line bonding pads WLBP may be arranged in each of the word line bonding regions 42a, 42b, and 42c. In this case, the word line bonding pads WLBP may be referred to as upper word line bonding pads.

The second semiconductor chip C2 may include a plurality of peripheral regions PERI, and components of a peripheral circuit (e.g., PECT of FIG. 1) may be arranged in each peripheral region PERI. Alternatively or additionally, the second semiconductor chip C2 may further include bit line bonding regions 43a, 43b, 43c, and 43d, and word line bonding regions 44a, 44b, and 44c. Bit line bonding pads BLBP may be arranged in each of the bit line bonding regions 43a, 43b, 43c, and 43d. In this case, the bit line bonding pads BLBP may be referred to as lower bit line bonding pads and may be connected to upper bit line bonding pads respectively corresponding thereto in a bonding manner. Word line bonding pads WLBP may be arranged in each of the word line bonding regions 44a, 44b, and 44c. In this case, the word line bonding pads WLBP may be referred to as lower word line bonding pads and may be connected to upper word line bonding pads corresponding thereto in a bonding manner.

FIG. 5 illustrates a memory device 50 according to an embodiment.

Referring to FIG. 5, the memory device 50 may include first and second semiconductor chips C1 and C2. The first semiconductor chip C1 may correspond to the first semiconductor chip C1 of FIG. 4, and the second semiconductor chip C2 may correspond to the second semiconductor chip C2 of FIG. 4, and descriptions given with reference to FIGS. 1 through 4 may also be applied to the memory device 50 of FIG. 5. The first semiconductor chip C1 may include a memory cell array 11, and the memory cell array 11 may be connected to bit lines BL1 to BL8, a ground selection line GSL, word lines WL1 to WLn, and a string selection line SSL.

The first semiconductor chip C1 may include upper bonding pads including first upper bonding pads UP1 and second upper bonding pads UP2, each of which is connected to the bit lines BL1 to BL8, the ground selection line GSL, the word lines WL1 to WLn, and the string selection line SSL. In this case, the width of the second upper bonding pad UP2 may be greater than the width of the first upper bonding pad UP1. The number of bit lines and word lines connected to the memory cell array 11 may be variously modified according to embodiments. Thus, the number of upper bonding pads included in the first semiconductor chip C1 may be variously modified according to embodiments.

The second semiconductor chip C2 may include a page buffer circuit 12, a pass transistor circuit 13a, a decoder circuit 13b, and a control logic circuit 14. For example, the pass transistor circuit 13a and the decoder circuit 13b may be included in the row decoder 13 of FIG. 1. The second semiconductor chip C2 may further include a voltage generator 15, an input/output circuit, or the like (not shown). The second semiconductor chip C2 may include lower bonding pads including the first lower bonding pads LP1.

In some embodiments, the number of upper bonding pads may be the same as the number of lower bonding pads, and the upper bonding pads and the lower bonding pads may be connected to each other in a one-to-one manner. In some embodiments, the number of upper bonding pads may be less than the number of lower bonding pads, and at least one upper bonding pad may be connected to at least two lower bonding pads. In some embodiments, the number of upper bonding pads may be greater than the number of lower bonding pads, and at least two upper bonding pads may be commonly connected to at least one lower bonding pad.

The bit lines BL1 to BL8 may be connected to the page buffer circuit 12 through the first upper bonding pads UP1 and the first lower bonding pads LP1 respectively corresponding to the first upper bonding pads UP1. The ground selection line GSL, the word lines WL1 to WLn, and the string selection line SSL may be connected to a pass transistor circuit 13a through the first upper bonding pads UP1 and the first lower bonding pads LP1 respectively corresponding to the first upper bonding pads UP1 or the second upper bonding pads UP2 and first lower bonding pads LP1 respectively corresponding to the second upper bonding pads UP2. For example, each of the ground selection line GSL and the word lines WL2, WLn-2, and WLn may be connected to the pass transistor circuit 13a through the second upper bonding pad UP2 and the first lower bonding pad LP1 corresponding to the second upper bonding pad UP2, and each of the word lines WL1, WL3, and WLn-1 and the string selection line SSL may be connected to the pass transistor circuit 13a through the first upper bonding pad UP1 and the first lower bonding pad LP1 corresponding to the first upper bonding pad UP1.

However, embodiments are not limited thereto. In some embodiments, the pass transistor circuit 13a may be arranged in the first semiconductor chip C1, and the decoder circuit 13b may be arranged in the second semiconductor chip C2, and the pass transistor circuit 13a and the decoder circuit 13b may be connected to each other through the first upper bonding pads UP1 and the first lower bonding pads LP1 respectively corresponding to the first upper bonding pads UP1 or the second upper bonding pads UP2 and the first lower bonding pads LP1 corresponding to the second upper bonding pads UP2. In some embodiments, the pass transistor circuit 13a and the decoder circuit 13b may be arranged in the first semiconductor chip C1, and the decoder circuit 13b and the control logic circuit 14 may be connected to each other through the first upper bonding pads UP1 and the first lower bonding pads LP1 corresponding to the first upper bonding pads UP1 or the second upper bonding pads UP2 and the first lower bonding pads LP1 corresponding to the second upper bonding pads UP2.

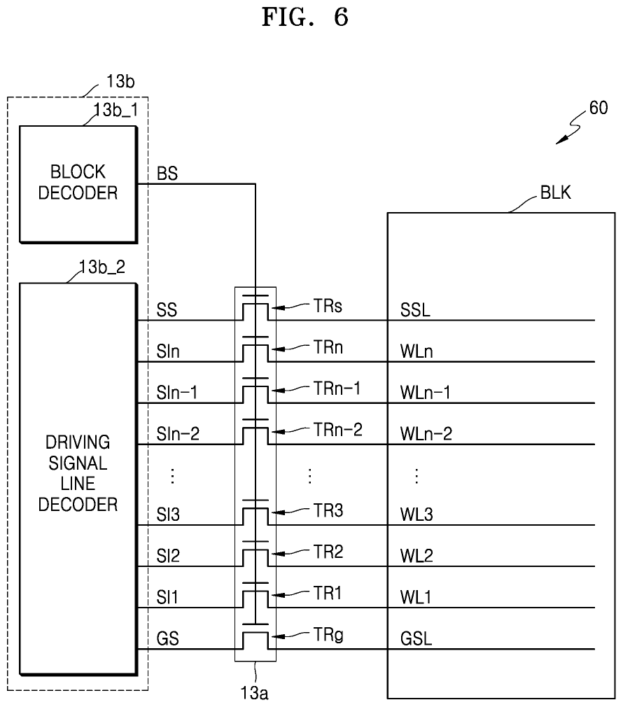

FIG. 6 illustrates a memory device 60 according to an embodiment.

Referring to FIG. 6, the memory device 60 may include a memory block BLK, a pass transistor circuit 13a, and a decoder circuit 13b. The decoder circuit 13b may include a block decoder 13b_1 and a driving signal line decoder 13b_2. For example, the pass transistor circuit 13a and the decoder circuit 13b may correspond to the pass transistor circuit 13a and the decoder circuit 13b of FIG. 5, respectively. As another example, the memory block BLK may correspond to one of the plurality of memory blocks BLK of FIG. 1.

The pass transistor circuit 13a may include a plurality of pass transistors TRg, TR1 to TRn, and TRs. The block decoder 13b_1 may be connected to the pass transistor circuit 13a through a block selection signal line BS. The block selection signal line BS may be connected to gates of the plurality of pass transistors TRg, TR1 to TRn, and TRs. For example, when a block selection signal provided through the block selection signal line BS is activated, the plurality of pass transistors TRg, TR1 to TRn, and TRs may be turned on. Thus, the memory block BLK may be selected.

The driving signal line decoder 13b_2 may be connected to the pass transistor circuit 13a through a ground selection line driving signal line GS, word line driving signal lines SI1 to SIn, and a string selection line driving signal line SS. In detail, the ground selection line driving signal line GS, the word line driving signal lines SI1 to SIn, and the string selection line driving signal line SS may be connected to sources of the plurality of pass transistors TRg, TR1 to TRn, and TRs.

The pass transistor circuit 13a may be connected to the memory block BLK through the ground selection line GSL, the word lines WL1 to WLn, and the string selection line SSL. The pass transistor TRg may be connected between the ground selection line driving signal line GS and the ground selection line GSL. The plurality of pass transistors TR1 to TRn may be connected between the word line driving signal lines SI1 to SIn and the word lines WL1 to WLn. The pass transistor TRs may be connected between the string selection line driving signal line SS and the string selection line SSL. For example, when the block selection signal is activated, the plurality of pass transistors TRg, TR1 to TRn, and TRs may provide driving signals provided through the ground selection line driving signal line GS, the word line driving signal lines SI1 to SIn, and the string selection line driving signal line SS to the ground selection line GSL, the word lines WL1 to WLn, and the string selection line SSL, respectively.

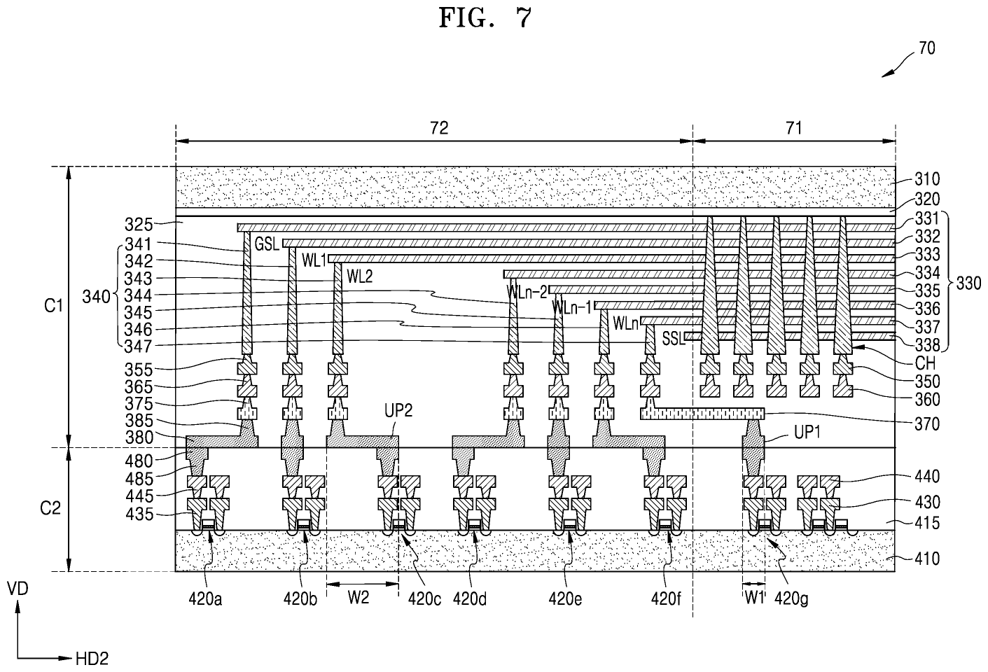

FIG. 7 is a cross-sectional view illustrating a memory device 70 according to an embodiment. The memory device 70 may correspond to an example of the memory device 50 of FIG. 5.

Referring to FIG. 7, a second semiconductor chip C2 of the memory device 70 may include a first substrate 410, an interlayer insulating layer 415, a plurality of circuit elements 420a to 420g formed on the first substrate 410, a first metal layer 430 connected to each of the plurality of circuit elements 420a to 420g, and a second metal layer 440 formed on the first metal layer 430. In some embodiments, the first metal layer 430 may be formed of tungsten having a relatively high resistance, and the second metal layer 440 may be formed of copper having a relatively low resistance. The first metal layer 430 may be connected to each of the plurality of circuit elements 420a to 420g through a first metal contact 435, and the second metal layer 440 may be connected to the first metal layer 430 through a second metal contact 445.

In the present disclosure, the first metal layer 430 and the second metal layer 440 are shown. However, embodiments are not limited thereto, and at least one metal layer may be further formed on the second metal layer 440. At least a portion of one or more metal layers formed on an upper portion of the second metal layer 440 may be formed of aluminum having a lower resistance than a resistance of copper used to form the second metal layer 440. The interlayer insulating layer 415 may be arranged on the first substrate 410 to cover the plurality of circuit elements 420a through 420g, the first metal layer 430, and the second metal layer 440, and may include an insulating material, such as silicon oxide, silicon nitride, or the like.

Lower bonding metals 480 or lower bonding pads 485 may be formed on the second metal layer 440. For example, the lower bonding pads 480 may respectively correspond to the first lower bonding pads LP1 of FIG. 5. As another example, each of the lower bonding pads 480 may have a first width W1 in the second direction HD2. As another example, widths of the lower bonding pads 480 may be the same. However, embodiments are not limited thereto. The lower bonding pads 480 and 485 of the second semiconductor chip C2 may be electrically connected to upper bonding metals 380 or upper bonding pads 385 of the first semiconductor chip C1 in a bonding manner, and the lower bonding pads 480 and 485 and the upper bonding pads 380 and 385 may be formed of aluminum, copper, or tungsten.

The first semiconductor chip C1 of the memory device 70 may provide at least one memory block (e.g., BLK of FIG. 6). The first semiconductor chip C1 may include a second substrate 310, a common source line 320, and an interlayer insulating layer 325. A plurality of gate electrodes 331 to 338 (e.g., 330) may be stacked on the second substrate 310 in a vertical direction VD perpendicular to a top surface of the second substrate 310. The plurality of gate electrodes 330 may include a ground selection line GSL, word lines WL1 to WLn, and a string selection line SSL. For example, the gate electrode 331 may correspond to the ground selection line GSL, and the gate electrodes 332 to 336 may correspond to the word lines WL1 to WLn, respectively, and the gate line 337 may correspond to the string selection line SSL. In some embodiments, the plurality of gate electrodes 330 may further include at least one dummy word line.

In a first region 71, a channel structure CH may extend in the vertical direction VD perpendicular to the top surface of the second substrate 310 and may pass through the plurality of gate electrodes 330. The channel structure CH may include a data storage layer, a channel layer, and a buried insulating layer, and the channel layer may be electrically connected to a first metal layer 350 and a second metal layer 360. The first metal layer 350 may be connected to the channel layer CH through a first metal contact 355, and the second metal layer 360 may be connected to the first metal layer 350 through a second metal contact 365. For example, the first metal layer 350 arranged in the first region 71 may be a bit line contact, and the second metal layer 360 arranged in the first region 71 may be bit lines (e.g., BL1 to BL8 of FIG. 5). In an example embodiment, the second metal layer 360 may extend in the second direction HD2 parallel to the top surface of the second substrate 310.

In the second region 72, a plurality of cell contact plugs 341 to 347 (e.g., 340) may pass through the interlayer insulating layer 325 in the vertical direction VD. The plurality of cell contact plugs 340 may be connected to the plurality of gate electrodes 330, respectively. The plurality of cell contact plugs 340 may be electrically connected to the first metal layer 350, the second metal layer 360, and a third metal layer 370. The first metal layer 350 may be connected to the plurality of cell contact plugs 340 through the first metal contact 355, the second metal layer 360 may be connected to the first metal layer 350 through the second metal contact 365, and the third metal layer 370 may be connected to the second metal layer 360 through a third metal contact 375. In some embodiments, the second region 72 may be referred to as a stepped region or word line bonding region (e.g., 42a, 42b, and 42c of FIG. 4).

The first semiconductor chip C1 may further include upper bonding metals or upper bonding pads 380 and 385. For example, in the first region 71, the upper bonding pad 380 may include a first upper bonding pad UP1, and the first upper bonding pad UP1 may have a first width W1 in the second direction HD2. As another example, in the second region 72, the upper bonding pad 380 may include a first upper bonding pad UP1 and a second upper bonding pad UP2, and the second upper bonding pad UP2 may have a second width W2 that is greater than the first width W1 of the first upper bonding pad UP1.

In the second region 72, the cell contact plugs 341 to 346 may be connected to the circuit elements 420a to 420f included in the second semiconductor chip C2 through the upper bonding pads 380 and 385 and the lower bonding metals or lower bonding pads 480 and 485. For example, the circuit elements 420a to 420f may be included in the pass transistor circuit 13a. As another example, the circuit elements 420a to 420f may correspond to the pass transistors TRg and TR1 to TRn of FIG. 6, respectively. As another example, the cell contact plugs 341, 343, 344, and 346 may be connected to the circuit elements 420a, 420c, 420d, and 420f included in the second semiconductor chip C2 through the second upper bonding pad UP2 and the lower bonding pads 480 and 485 of the second semiconductor chip C2. For example, the cell contact plugs 342 and 345 may be respectively connected to the circuit elements 420b and 420e included in the second semiconductor chip C2 through the first upper bonding pad UP1 and the lower bonding pads 480 and 485 of the second semiconductor chip C2.

In the first region 71, the cell contact plug 347 may be connected to the circuit element 420g included in the second semiconductor chip C2 through the upper bonding pads 380 and 385 and the lower bonding pads 480 and 485. In detail, the cell contact plug 347 arranged in the second region 72 may be connected to the upper bonding pads 380 and 385 arranged in the first region 71 through a linear metal pattern included in the third metal layer 370. In this case, the linear metal pattern may be a linear metal pattern extending in the second direction HD2. For example, the circuit element 420g may be included in the pass transistor circuit 13a. For example, the circuit element 420g may correspond to the pass transistor TRs of FIG. 6. As another example, the cell contact plug 347 may be connected to the circuit element 420a included in the second semiconductor chip C2 through the first upper bonding pad UP1 and the lower bonding pads 480 and 485 of the second semiconductor chip C2.

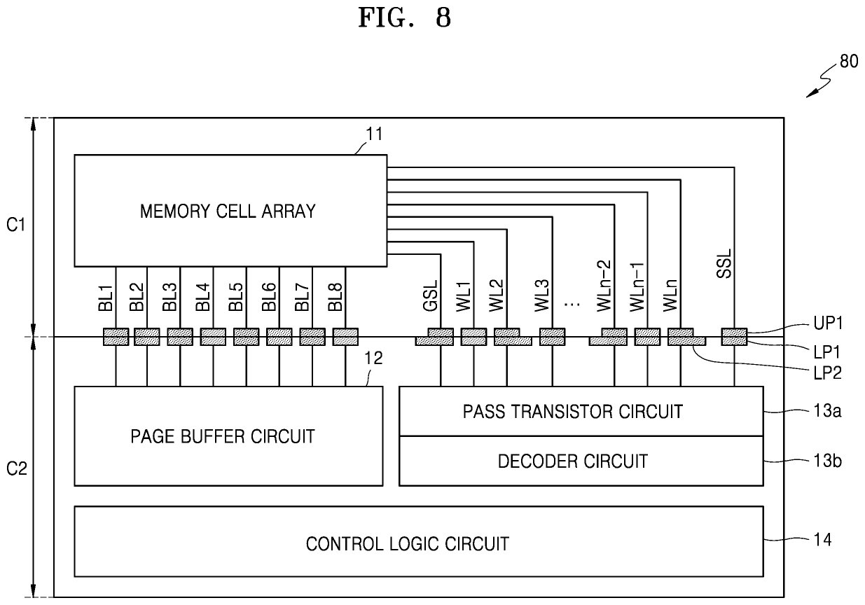

FIG. 8 illustrates a memory device 80 according to an embodiment.

Referring to FIG. 8, the memory device 80 may correspond to a modified example of the memory device 50 of FIG. 5, and a redundant description thereof is omitted. A first semiconductor chip C1 of the memory device 80 may include a plurality of upper bonding pads including first upper bonding pads UP1, and a second semiconductor chip C2 of the memory device 80 may include a plurality of lower bonding pads including first lower bonding pads LP1 and second lower bonding pads LP2. In some embodiments, the width of the second lower bonding pad LP2 may be greater than the width of the first lower bonding pad LP1.

The ground selection line GSL, the word lines WL1 to WLn, and the string selection line SSL may be connected to a pass transistor circuit 13a through the first upper bonding pads UP1 and the first lower bonding pads LP1 or the first upper bonding pads UP1 and second lower bonding pads LP2. For example, each of the ground selection line GSL and the word lines WL2, WLn-2, and WLn may be connected to the pass transistor circuit 13a through the first upper bonding pad UP1 and the second upper bonding pad UP2 corresponding to the first upper bonding pad UP1, and each of the word lines WL1, WL3, and WLn-1 and the string selection line SSL may be connected to the pass transistor circuit 13a through the first upper bonding pad UP1 and the second lower bonding pad LP2 corresponding to the first upper bonding pad UP1.

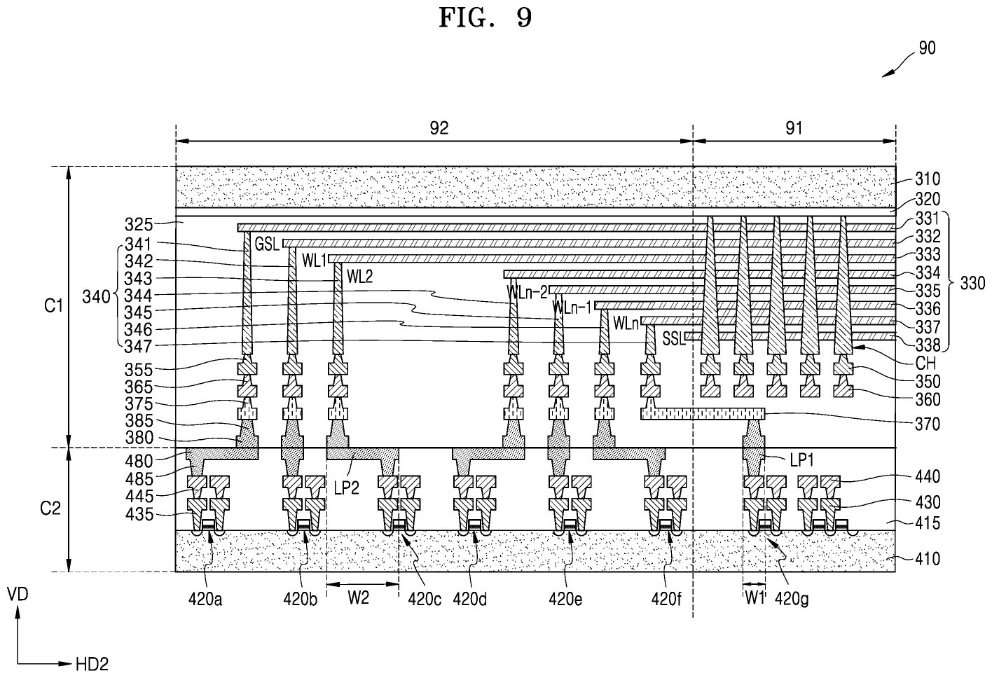

FIG. 9 is a cross-sectional view illustrating a memory device 90 according to an embodiment. The memory device 90 may correspond to an example of the memory device 80 of FIG. 8.

Referring to FIG. 9, the memory device 90 may correspond to a modified example of the memory device 70 of FIG. 7, and a redundant description thereof is omitted. Lower bonding pads 480 of a second semiconductor chip C2 may include first lower bonding pads LP1 and second lower bonding pads LP2. For example, the lower bonding pads 480 may correspond to the first and second lower bonding pads LP1 and LP2 of FIG. 8. As another example, each of the first lower bonding pads LP1 may have a first width W1 in a second direction HD2, and each of the second lower bonding pads LP2 may have a second width W2 that is greater than the first width W1 of the first lower bonding pad LP1 in the second direction HD2. Each of the upper bonding pads 380 of the first semiconductor chip C1 may have the first width W1 in the second direction HD2. However, embodiments are not limited thereto, and widths of the upper bonding pads 380 may be different from each other. For example, the upper bonding pads 380 of the first semiconductor chip C1 may correspond to the first upper bonding pads UP1 of FIG. 8.

In a second region 92, cell contact plugs 341 to 346 may be respectively connected to circuit elements 420a to 420f included in the second semiconductor chip C2 through the upper bonding pads 380 and 385 and the lower bonding metals or lower bonding pads 480 and 485. For example, the cell contact plugs 341, 343, 344, and 346 may be respectively connected to the circuit elements 420a, 420c, 420d, and 420f included in the second semiconductor chip C2 through the upper bonding pads 380 and the second lower bonding pads LP2 of the second semiconductor chip C2. As another example, each of the cell contact plugs 342 and 345 may be respectively connected to the circuit elements 420b and 420e included in the second semiconductor chip C2 through the upper bonding pads 380 and the first lower bonding pads LP1 of the second semiconductor chip C2.

In a first region 91, the cell contact plug 347 may be connected to the circuit element 420g included in the second semiconductor chip C2 through the upper bonding pads 380 and 385 and the lower bonding pads 480 and 485. In detail, the cell contact plug 347 arranged in the second region 72 may be respectively connected to the upper bonding pads 380 and 385 arranged in the first region 91 through a linear metal pattern included in the third metal layer 370. For example, the cell contact plug 347 may be connected to the circuit element 420g included in the second semiconductor chip C2 through the upper bonding pads 380 and the first lower bonding pads LP1 of the second semiconductor chip C2.

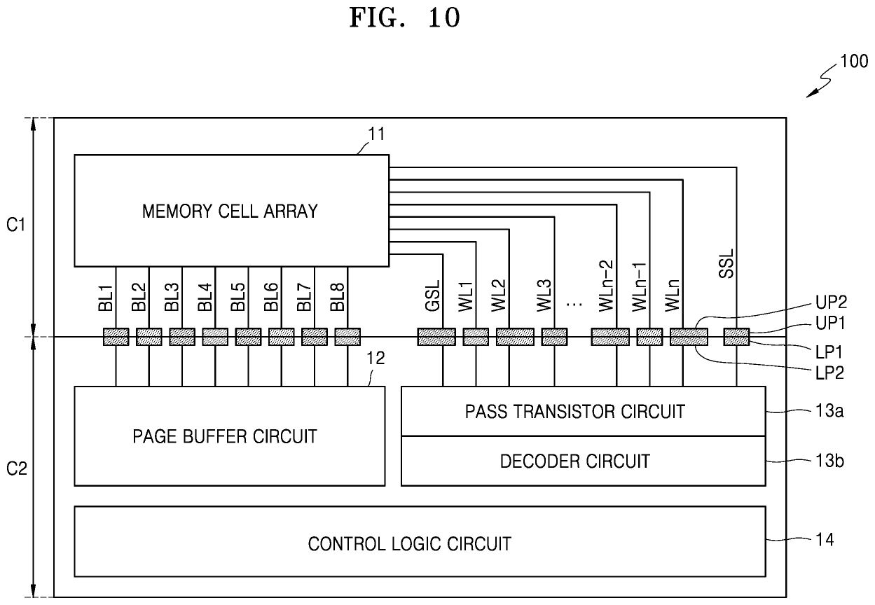

FIG. 10 illustrates a memory device 100 according to an embodiment.

Referring to FIG. 10, the memory device 100 may correspond to a modified example of the memory device 50 of FIG. 5 or the memory device 80 of FIG. 8, and a redundant description thereof is omitted. The first semiconductor chip C1 of the memory device 100 may include a plurality of upper bonding pads including first upper bonding pads UP1 and second upper bonding pads UP2, and the second semiconductor chip C2 of the memory device 100 may include a plurality of lower bonding pads including first lower bonding pads LP1 and second lower bonding pads LP2. In some embodiments, the width of the second upper bonding pad UP2 may be greater than the width of the first upper bonding pad UP1. Alternatively or additionally, the width of the second lower bonding pad LP2 may be greater than the width of the first lower bonding pad LP1.

The ground selection line GSL, the word lines WL1 to WLn, and the string selection line SSL may be connected to a pass transistor circuit 13a through the first upper bonding pads UP1 and the first lower bonding pads LP1 corresponding to the first upper bonding pads UP1 or the second upper bonding pads UP2 and second lower bonding pads LP2 corresponding to the second upper bonding pads UP2. For example, each of the ground selection line GSL and the word lines WL2, WLn-2, and WLn may be connected to the pass transistor circuit 13a through the second upper bonding pad UP2 and the second lower bonding pad LP2 corresponding to the second upper bonding pad UP2, and each of the word lines WL1, WL3, and WLn-1 and the string selection line SSL may be connected to the pass transistor circuit 13a through the first upper bonding pad UP1 and the first lower bonding pad LP1 corresponding to the first upper bonding pad UP1.

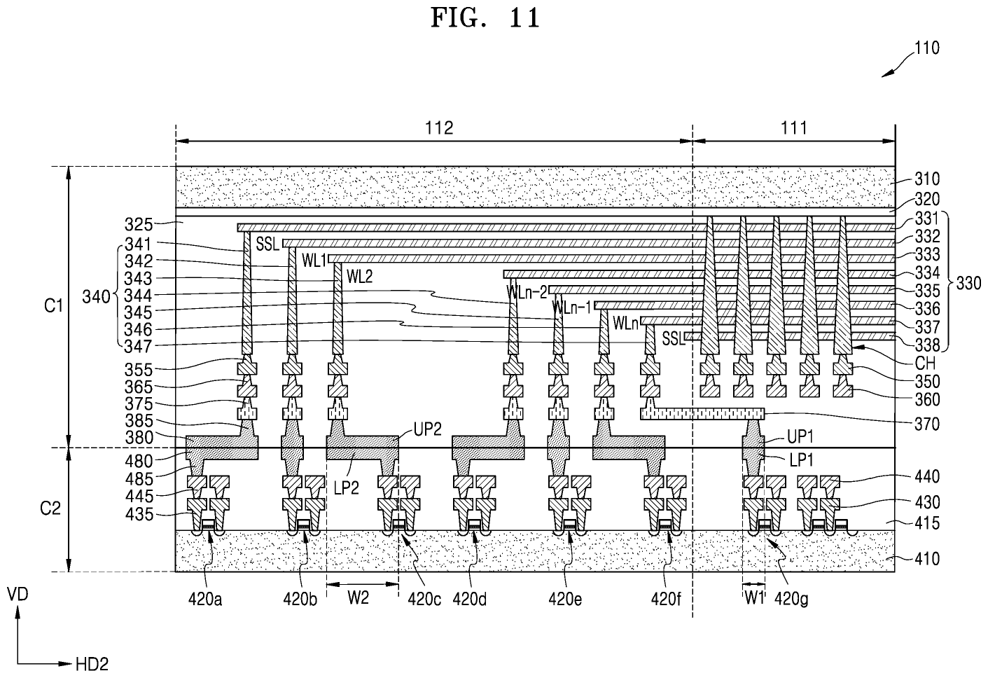

FIG. 11 is a cross-sectional view illustrating a memory device 110 according to an embodiment. The memory device 110 may correspond to an example of the memory device 100 of FIG. 10.

Referring to FIG. 11, the memory device 110 may correspond to a modified example of the memory device 70 of FIG. 7, and a redundant description thereof is omitted. Upper bonding pads 380 of a first semiconductor chip C1 may include first upper bonding pads UP1 and second upper bonding pads UP2. For example, the upper bonding pads 380 may correspond to the first and second upper bonding pads UP1 and UP2 of FIG. 10. As another example, each of the first upper bonding pads UP1 may have a first width W1 in a second direction HD2, and each of the second upper bonding pads UP2 may have a second width W2 that is greater than the first width W1 in the second direction HD2.

Lower bonding pads 480 of a second semiconductor chip C2 may include first lower bonding pads LP1 and second lower bonding pads LP2. For example, the lower bonding pads 480 may correspond to the first and second lower bonding pads LP1 and LP2 of FIG. 10. As another example, each of the first lower bonding pads LP1 may have a first width W1 in a second direction HD2, and each of the second lower bonding pads LP2 may have a second width W2 that is greater than the first width W1 in the second direction HD2.

In a second region 102, cell contact plugs 341 to 346 may be respectively connected to circuit elements 420a to 420f included in the second semiconductor chip C2 through the upper bonding pads 380 and 385 and the lower bonding pads 480 and 485. For example, the cell contact plugs 341, 343, 344, and 346 may be connected to the circuit elements 420a, 420c, 420d, and 420f included in the second semiconductor chip C2 through the second upper bonding pads UP2 and the second lower bonding pads LP2. As another example, each of the cell contact plugs 342 and 345 may be connected to the circuit elements 420b and 420e included in the second semiconductor chip C2 through the upper bonding pads UP1 and the first lower bonding pads LP1.

In a first region 101, the cell contact plug 347 may be connected to the circuit element 420g included in the second semiconductor chip C2 through the upper bonding pads 380 and 385 and the lower bonding pads 480 and 485. That is, the cell contact plug 347 arranged in the second region 102 may be connected to the upper bonding pads 380 and 385 arranged in the first region 101 through a linear metal pattern included in the third metal layer 370. For example, the cell contact plug 347 may be connected to the circuit element 420g included in the second semiconductor chip C2 through the first upper bonding pad UP1 and the first lower bonding pad LP1.

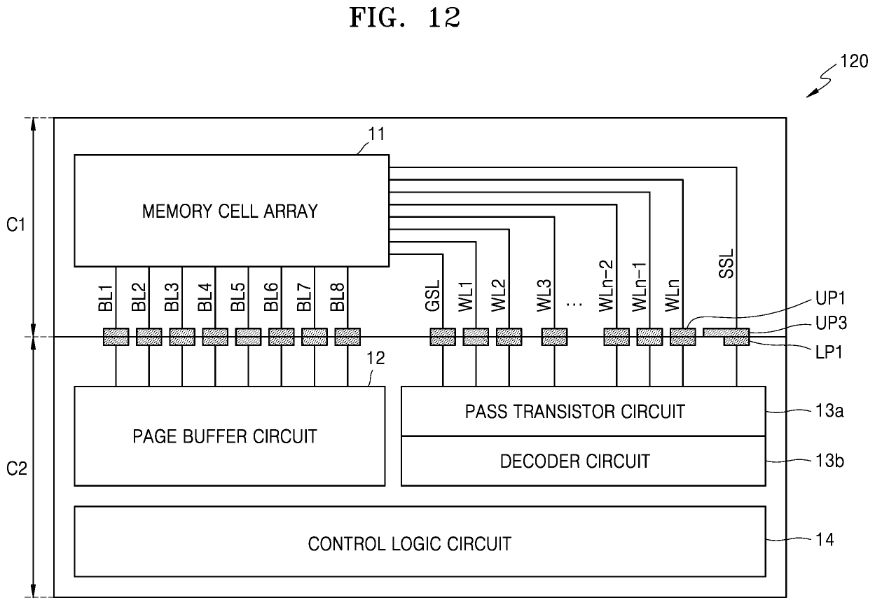

FIG. 12 illustrates a memory device 120 according to an embodiment.

Referring to FIG. 12, the memory device 120 may correspond to a modified example of the memory device 50 of FIG. 5, the memory device 80 of FIG. 8, or the memory device 100 of FIG. 10, and a redundant description thereof is omitted. The first semiconductor chip C1 of the memory device 120 may include a plurality of upper bonding pads including first upper bonding pads UP1 and a third upper bonding pad UP3, and the second semiconductor chip C2 of the memory device 120 may include a plurality of lower bonding pads including first lower bonding pads LP1. In some embodiments, the width of the third upper bonding pad UP3 may be greater than the width of the first upper bonding pad UP1.

The ground selection line GSL and the word lines WL1 to WLn may be connected to the pass transistor circuit 13a through the first upper bonding pads UP1 and the first lower bonding pads LP1 corresponding to the first upper bonding pads UP1. The string selection line SSL may be connected to the pass transistor circuit 13a through the third upper bonding pad UP3 and a first lower bonding pad LP1 corresponding to the third upper bonding pad UP3.

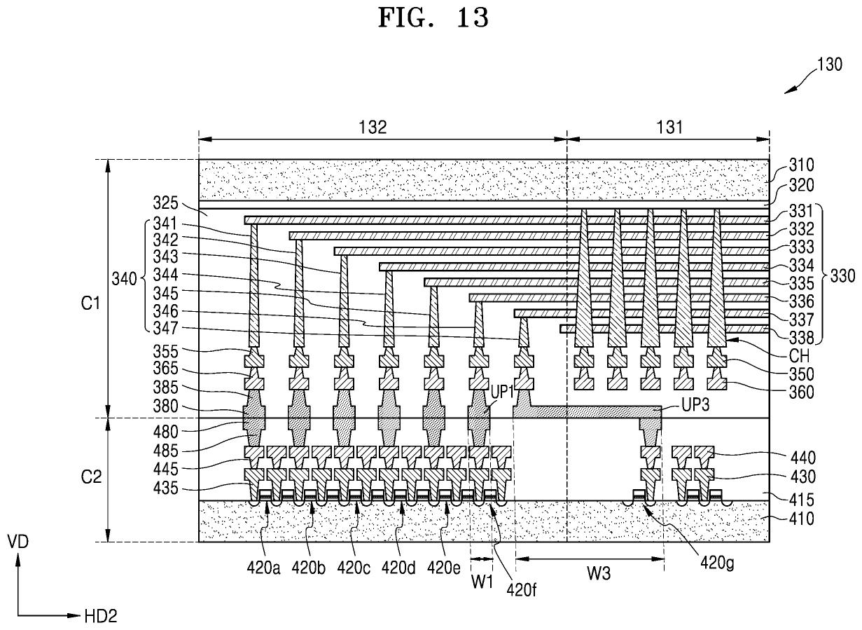

FIG. 13 is a cross-sectional view illustrating a memory device 130 according to an embodiment. The memory device 130 may correspond to an example of the memory device 120 of FIG. 12.

Referring to FIG. 13, the memory device 130 may correspond to a modified example of the memory device 70 of FIG. 7, and a redundant description thereof is omitted. Lower bonding pads 480 of a second semiconductor chip C2 may include first lower bonding pads LP1 of FIG. 12, for example. In some embodiments, each of the lower bonding pads 480 may have a first width W1 in the second direction HD2. Upper bonding pads 380 of a first semiconductor chip C1 may include first upper bonding pads UP1 and third upper bonding pads UP3. For example, the upper bonding pads 380 may correspond to the first and third upper bonding pads UP1 and UP3 of FIG. 12. As another example, each of the first upper bonding pads UP1 may have a first width W1 in a second direction HD2, and each of the third upper bonding pads UP3 may have a third width W3 that is greater than the first width W1 in the second direction HD2.

In a second region 132, a plurality of cell contact plugs 341 to 346 may be electrically connected to a first metal layer 350, a second metal layer 360, and a first upper bonding pad UP1. The first metal layer 350 may be connected to the plurality of cell contact plugs 340 through the first metal contact 355, the second metal layer 360 may be connected to the first metal layer 350 through the second metal contact 365, and the first upper bonding pad UP1 may be connected to the second metal layer 360 through the upper bonding metal or upper bonding pad 385. For example, each of the cell contact plugs 341 to 346 may be connected to the circuit elements 420a to 420f included in the second semiconductor chip C2 through the first upper bonding pad UP1 and the lower bonding pads 480 and 485.

In a first region 131, a channel structure CH may extend in the vertical direction VD perpendicular to the top surface of the second substrate 310 and may pass through a plurality of gate electrodes 330. The channel structure CH may include a data storage layer, a channel layer, and a buried insulating layer, and the channel layer may be electrically connected to the first metal layer 350 and the second metal layer 360. The cell contact plug 347 may be electrically connected to the first metal layer 350, the second metal layer 360, and the third upper bonding pad UP3. For example, the cell contact plug 347 may be connected to the circuit element 420g included in the second semiconductor chip C2 through the third upper bonding pad UP3 and the lower bonding pads 480 and 485.

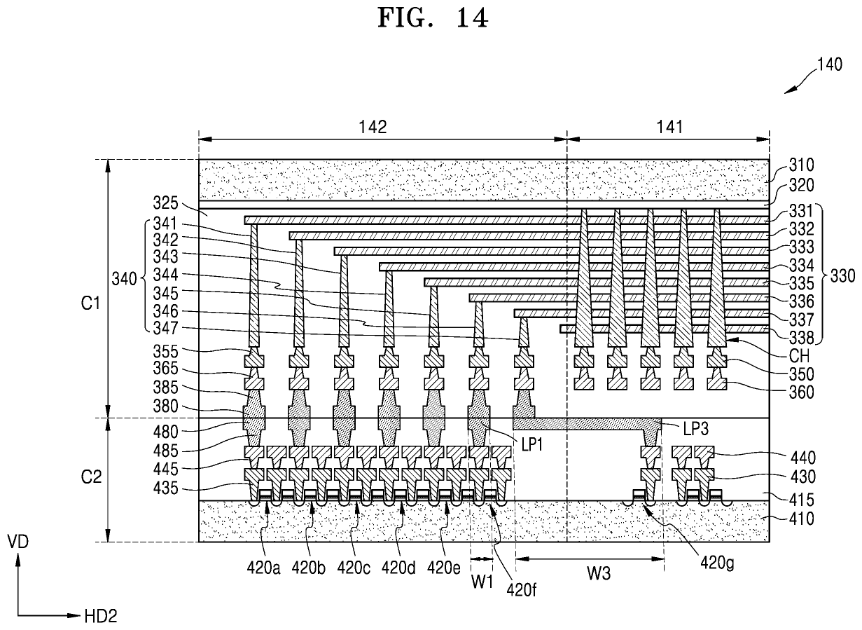

FIG. 14 is a cross-sectional view illustrating a memory device 140 according to an embodiment. The memory device 140 may correspond to a modified example of the memory device 130 of FIG. 13, and a redundant description thereof is omitted.

Referring to FIG. 14, lower bonding pads 480 of a second semiconductor chip C2 may include first lower bonding pads LP1 and third lower bonding pads LP3. For example, each of the first upper bonding pads UP1 may have a first width W1 in a second direction HD2, and each of the third upper bonding pads UP3 may have a third width W3 that is greater than the first width W1 in the second direction HD2. Each of the upper bonding pads 380 of the first semiconductor chip C1 may have the first width W1 in the second direction HD2.

In a second region 142, cell contact plugs 341 to 346 may be connected to circuit elements 420a to 420f included in the second semiconductor chip C2 through the upper bonding pads 380 and 385 and the lower bonding pads 480 and 485. In a first region 141, a channel structure CH may extend in the vertical direction VD perpendicular to the top surface of the second substrate 310 and may pass through a plurality of gate electrodes 330. The cell contact plug 347 may be electrically connected to the first metal layer 350, the second metal layer 360, and the upper bonding pad 380. For example, the cell contact plug 347 may be connected to the circuit element 420g included in the second semiconductor chip C2 through the upper bonding pad 380 and the third lower bonding pad LP3.

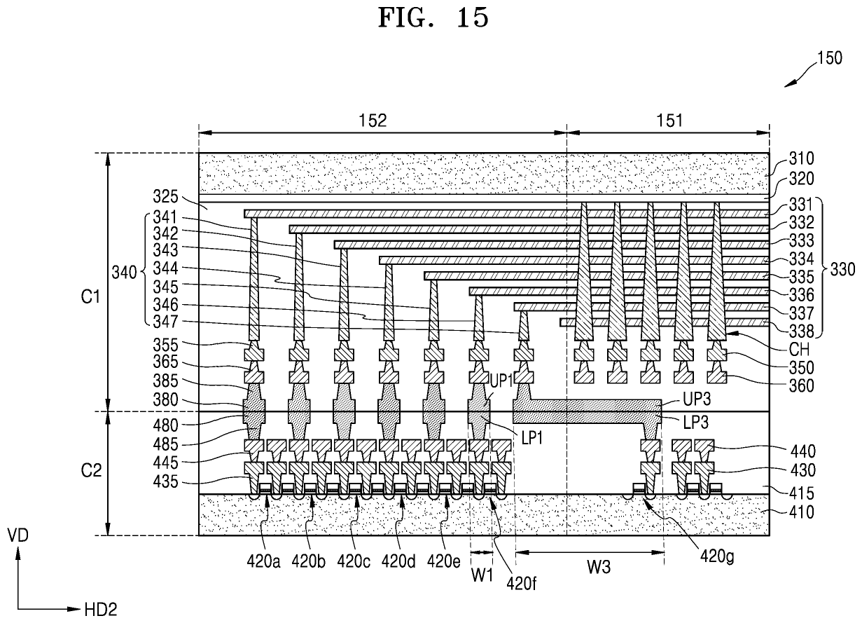

FIG. 15 is a cross-sectional view illustrating a memory device 150 according to an embodiment. The memory device 150 may correspond to a modified example of the memory device 130 of FIG. 13, and a redundant description thereof is omitted.

Referring to FIG. 15, lower bonding pads 480 of a second semiconductor chip C2 may include first lower bonding pads LP1 and third lower bonding pads LP3. For example, each of the first lower bonding pads LP1 may have a first width W1 in a second direction HD2, and each of the third lower bonding pads LP3 may have a third width W3 that is greater than the first width W1 in the second direction HD2. Upper bonding pads 380 of a first semiconductor chip C1 may include first upper bonding pads UP1 and third upper bonding pads UP3. For example, each of the first upper bonding pads UP1 may have a first width W1 in a second direction HD2, and each of the third upper bonding pads UP3 may have a third width W3 that is greater than the first width W1 in the second direction HD2.

In a second region 152, cell contact plugs 341 to 346 may be connected to circuit elements 420a to 420f included in the second semiconductor chip C2 through the upper bonding pads 380 and 385 and the lower bonding pads 480 and 485. In a first region 151, a channel structure CH may extend in the vertical direction VD perpendicular to the top surface of the second substrate 310 and may pass through a plurality of gate electrodes 330. The cell contact plug 347 may be electrically connected to the first metal layer 350, the second metal layer 360, and the third upper bonding pad UP3. For example, the cell contact plug 347 may be connected to the circuit element 420g included in the second semiconductor chip C2 through the third upper bonding pad UP3 and the third lower bonding pad LP3.

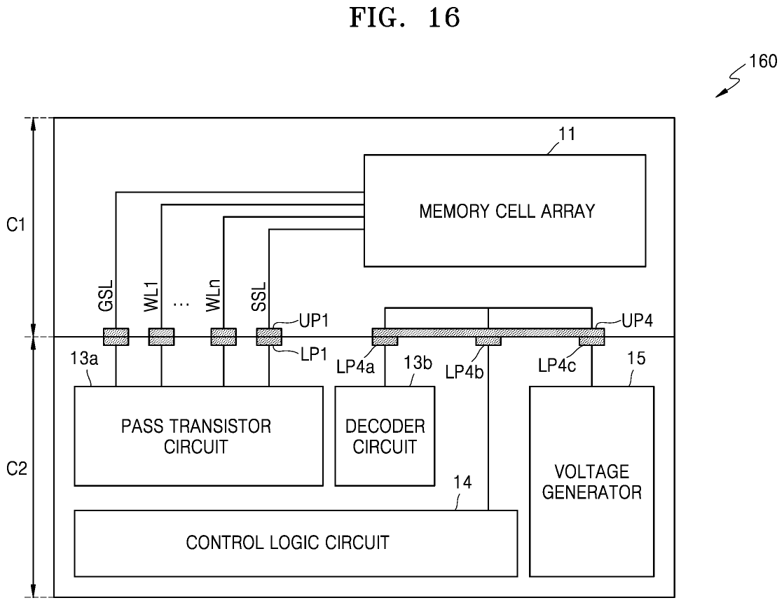

FIG. 16 illustrates a memory device 160 according to an embodiment.

Referring to FIG. 16, the memory device 160 may correspond to a modified example of the memory device 50 of FIG. 5, the memory device 80 of FIG. 8, the memory device 100 of FIG. 10 or the memory device 120 of FIG. 12, and a redundant description thereof is omitted. The first semiconductor chip C1 of the memory device 160 may include a plurality of upper bonding pads including first upper bonding pads UP1 and fourth upper bonding pads UP4, and the second semiconductor chip C2 of the memory device 160 may include first lower bonding pads LP1 and fourth lower bonding pads LP4a, LP4b, and LP4c. The ground selection line GSL and the word lines WL1 to WLn may be connected to the pass transistor circuit 13a through the first upper bonding pads UP1 and the first lower bonding pads LP1 corresponding to the first upper bonding pads UP1.

Peripheral circuits included in the second semiconductor chip C2 may be electrically connected to each other through the fourth lower bonding pads LP4a, LP4b, and LP4c, and the fourth upper bonding pad UP4. For example, the decoder circuit 13b and the voltage generator 15 may be electrically connected to each other through the fourth lower bonding pads LP4a and LP4c and the fourth upper bonding pad UP4. Thus, a voltage generated by the voltage generator 15 (e.g., the word line voltage VWL of FIG. 1), the string selection line voltage (e.g., VSSL of FIG. 1), and the ground selection line voltage (e.g., VGSL of FIG. 1) may be provided to the decoder circuit 13b. As another example, the control logic circuit 14 and the voltage generator 15 may be electrically connected to each other through the fourth lower bonding pads LP4b and LP4c and the fourth upper bonding pad UP4. Thus, a voltage control signal CTRL_vol generated by the control logic circuit 14 may be provided to the voltage generator 15. As another example, the control logic circuit 14 and the decoder circuit 13b may be electrically connected to each other through the fourth lower bonding pads LP4a and LP4b and the fourth upper bonding pad UP4. Thus, a row address (X_ADDR of FIG. 1) generated by the control logic circuit 14 may be provided to the decoder circuit 13b. In this way, the decoder circuit 13b, the control logic circuit 14 and/or the voltage generator 15 may be electrically connected to each other through the fourth lower bonding pads LP4a, LP4b, and LP4c, and the fourth upper bonding pad UP4.

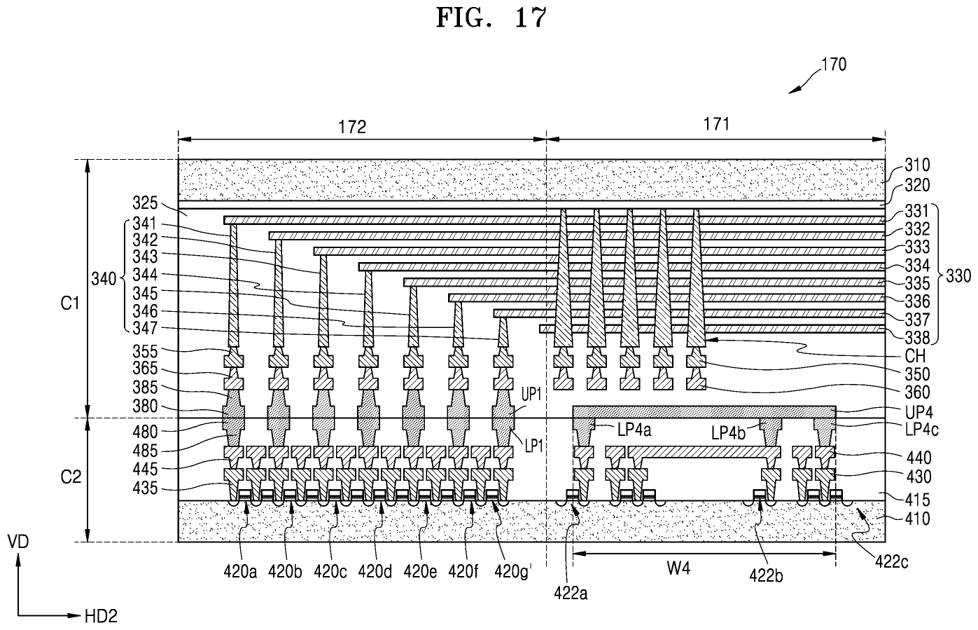

FIG. 17 is a cross-sectional view illustrating a memory device 170 according to an embodiment. The memory device 170 may correspond to an example of the memory device 160 of FIG. 16.

Referring to FIG. 17, the memory device 170 may correspond to a modified example of the memory device 70 of FIG. 7, and a redundant description thereof is omitted. The second semiconductor chip C2 may include circuit elements 422a, 422b, and 422c arranged in the first region 171, and circuit elements 420a to 420g′ arranged in the second region 172. Lower bonding pads 480 of the second semiconductor chip C2 may include first lower bonding pads LP1 and fourth lower bonding pads LP4a, LP4b, and LP4c. Upper bonding pads 380 of the first semiconductor chip C1 may include first upper bonding pads UP1 and a fourth upper bonding pad UP4. For example, the fourth upper bonding pad UP4 and the fourth lower bonding pads LP4a, LP4b, and LP4c may be arranged in the first region 171. As another example, the width of the fourth upper bonding pad UP4 may be greater than the width of the first upper bonding pad UP1. As another example, the fourth upper bonding pad UP4 may have a fourth width W4 in the second direction HD2.

In a second region 172, each of cell contact plugs 340 may be connected to circuit elements 420a to 420g′ included in the second semiconductor chip C2 through the upper bonding pads 380 and 385 and the lower bonding pads 480 and 485. In the first region 171, the fourth lower bonding pads LP4a, LP4b, and LP4c may be commonly connected to the fourth upper bonding pad UP4, and the circuit elements 422a, 422b, and 422c may be connected to the fourth lower bonding pads LP4a, LP4b, and LP4c through the fourth upper bonding pad UP4. For example, the circuit element 422a may be included in the decoder circuit 13b, the circuit element 422b may be included in the control logic circuit 14, and the circuit element 422c may be included in the voltage generator 15. However, embodiments are not limited thereto.

In some embodiments, the circuit element 422a may be connected to the circuit element 422c through the first metal layer 430, the second metal layer 440, the fourth lower bonding pad LP4a, the fourth upper bonding pad UP4, and the fourth lower bonding pad LP4c. For example, the circuit element 422a may be connected to the circuit element 422b through the first metal layer 430, the second metal layer 440, the fourth lower bonding pad LP4a, the fourth upper bonding pad UP4, and the fourth lower bonding pad LP4b. In this case, the second metal layer 440 may include a linear metal pattern extending in the second direction HD2, and the circuit element 422b may be connected to a different circuit element through the linear metal pattern. For example, the circuit element 422b may be connected to the circuit element 422c through the first metal layer 430, the second metal layer 440, the fourth lower bonding pad LP4b, the fourth upper bonding pad UP4, and the fourth lower bonding pad LP4c.

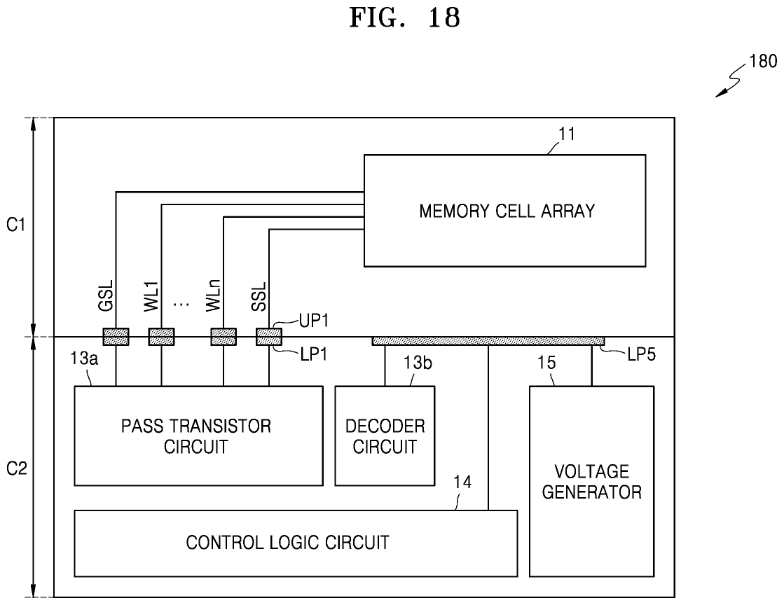

FIG. 18 illustrates a memory device 180 according to an embodiment.

Referring to FIG. 18, the memory device 180 may correspond to a modified example of the memory device 160 of FIG. 16, and a redundant description thereof is omitted. A first semiconductor chip C1 of the memory device 180 may include upper bonding pads including first upper bonding pads UP1, and a second semiconductor chip C2 of the memory device 180 may include lower bonding pads including first lower bonding pads LP1 and fifth lower bonding pads LP5. Peripheral circuits included in the second semiconductor chip C2 may be electrically connected to each other through the fifth lower bonding pad LP5. For example, the decoder circuit 13b, the control logic circuit 14 and/or the voltage generator 15 may be electrically connected to each other through the fifth lower bonding pad LP5.

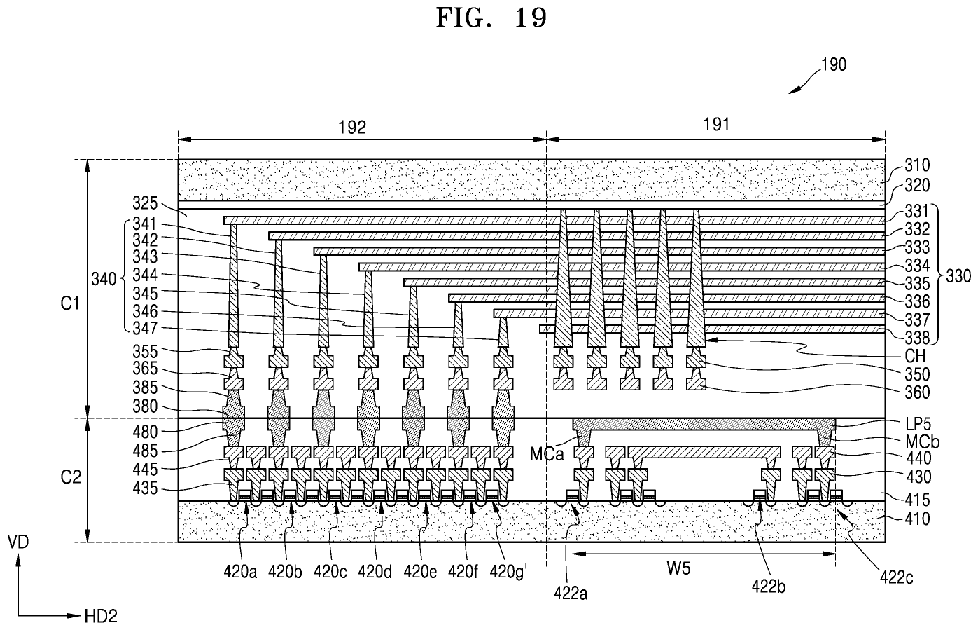

FIG. 19 is a cross-sectional view illustrating a memory device 190 according to an embodiment. The memory device 190 may correspond to an example of the memory device 180 of FIG. 18.

Referring to FIG. 19, the memory device 190 may correspond to a modified example of the memory device 170 of FIG. 17, and a redundant description thereof is omitted. Lower bonding pads 480 of a second semiconductor chip C2 may include first lower bonding pads LP1 and fifth lower bonding pads LP5. For example, the first lower bonding pads LP1 may be arranged in the second region 192, and the fifth lower bonding pad LP5 may be arranged in the first region 191. For example, the width of the fifth lower bonding pad LP5 may be greater than the width of the first lower bonding pad LP1. As another example, the fifth lower bonding pad LP5 may have a fifth width W5 in the second direction HD2.

In a second region 192, cell contact plugs 340 may be respectively connected to circuit elements 420a to 420g′ included in the second semiconductor chip C2 through the upper bonding pads 380 and 385 and the lower bonding pads 480 and 485. In a first region 191, the circuit elements 422a and 422c may be commonly connected to the fifth lower bonding pad LP5. For example, the circuit element 422a may be connected to the circuit element 422c through the first metal layer 430, the second metal layer 440, and the fifth lower bonding pad LP5. As another example, the circuit element 422b may be connected to an adjacent circuit element through the first metal layer 430 and the second metal layer 440. In this case, the second metal layer 440 may include a linear metal pattern extending in the second direction HD2, and the circuit element 422b may be connected to an adjacent circuit element through the linear metal pattern.

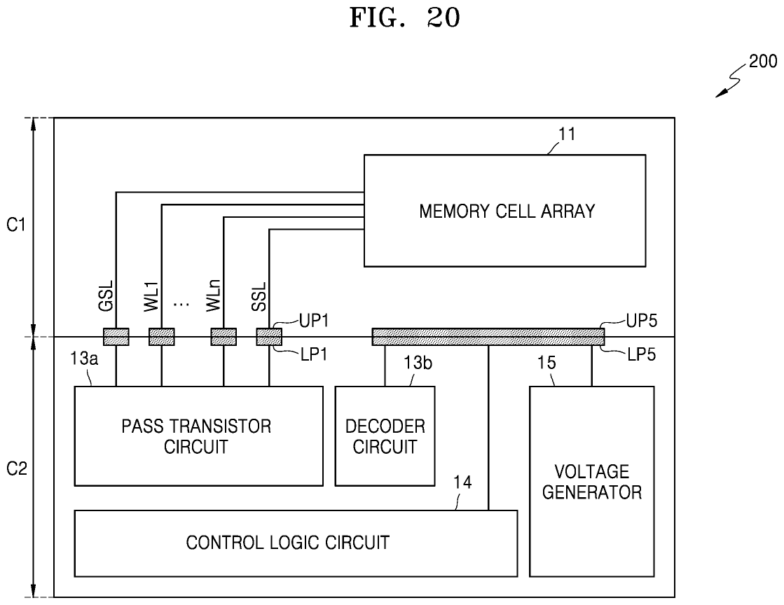

FIG. 20 illustrates a memory device 200 according to an embodiment.

Referring to FIG. 20, the memory device 200 may correspond to a modified example of the memory device 160 of FIG. 16 or the memory device 180 of FIG. 18, and a redundant description thereof is omitted. A first semiconductor chip C1 of the memory device 200 may include first upper bonding pads UP1 and fifth upper bonding pads UP5, and a second semiconductor chip C2 of the memory device 200 may include first lower bonding pads LP1 and a fifth lower bonding pad LP5. Peripheral circuits included in the second semiconductor chip C2 may be electrically connected to each other through the fifth lower bonding pad LP5 and the fifth upper bonding pad UP5. For example, the decoder circuit 13b, the control logic circuit 14 and/or the voltage generator 15 may be electrically connected to each other through the fifth lower bonding pad LP5 and the fifth upper bonding pad UP5.

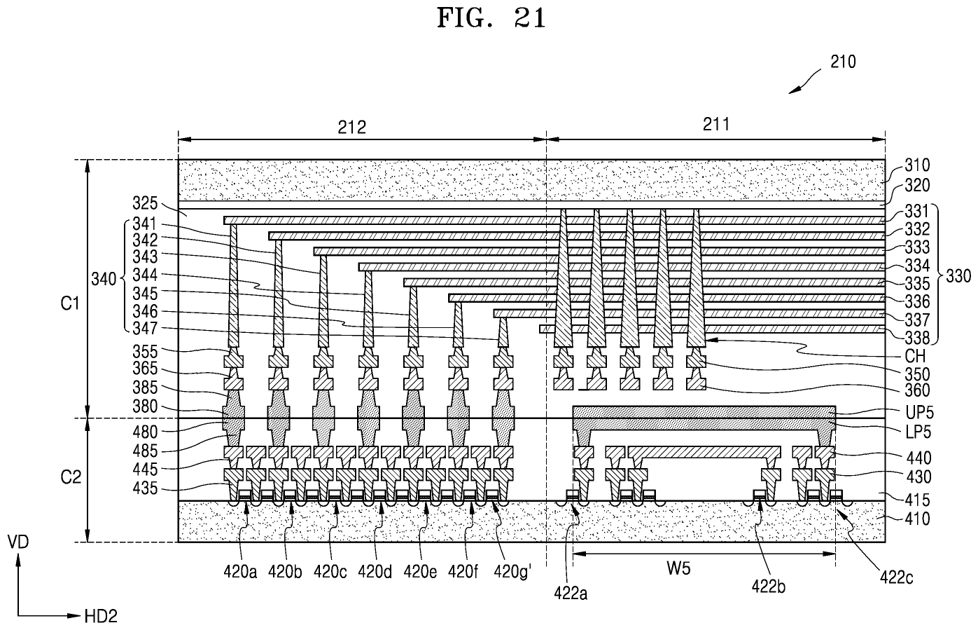

FIG. 21 is a cross-sectional view illustrating a memory device 210 according to an embodiment. The memory device 210 may correspond to an example of the memory device 200 of FIG. 20.

Referring to FIG. 21, the memory device 210 may correspond to a modified example of the memory device 190 of FIG. 19, and a redundant description thereof is omitted. Upper bonding pads 380 of the first semiconductor chip C1 may include first upper bonding pads UP1 and a fifth upper bonding pad UP5. For example, the first upper bonding pads UP1 may be arranged in the second region 212, and the fifth upper bonding pad UP5 may be arranged in the first region 211. As another example, widths of the fifth lower bonding pad LP5 and the fifth upper bonding pad UP5 may be greater than widths of the first lower bonding pad LP1 and the fifth upper bonding pad UP1. For example, the fifth lower bonding pad LP5 and the fifth upper bonding pad UP5 may have a fifth width W5 in the second direction HD2.

In a second region 212, cell contact plugs 340 may be respectively connected to circuit elements 420a to 420g′ included in the second semiconductor chip C2 through the upper bonding pads 380 and 385 and the lower bonding pads 480 and 485. In a first region 211, the circuit elements 422a and 422c may be commonly connected to the fifth lower bonding pad LP5. For example, the circuit element 422a may be connected to the circuit element 422c through the first metal layer 430, the second metal layer 440, the fifth lower bonding pad LP5, and the fifth upper bonding pad UP5.

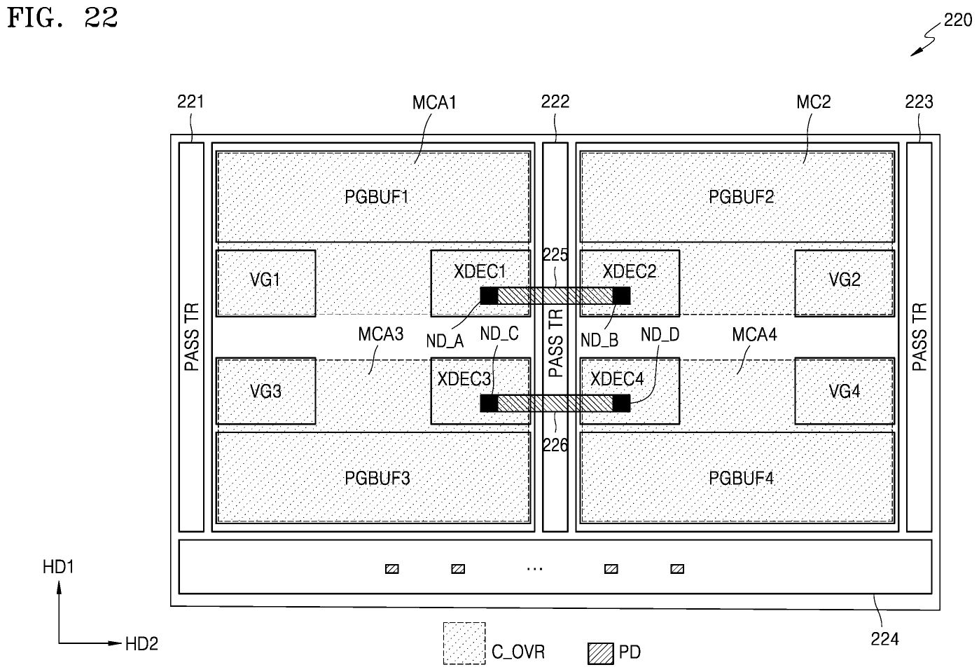

FIG. 22 illustrates a memory device 220 according to an embodiment.

Referring to FIG. 22, a lower semiconductor layer or a lower semiconductor chip of the memory device 220 may include first through fourth page buffer circuits PGBUF1 to PGBUF4, first to fourth row decoders XDEC1 to XDEC4, first to fourth voltage generators VG1 to VG4, pass transistor circuits 221, 222, and 223, and a pad region 224, and a plurality of bonding pads PD may be arranged in the pad region 224. For example, the memory device 220 may have a C2C bonding structure as illustrated in FIG. 4, and an upper semiconductor layer or an upper semiconductor chip of the memory device 220 may include first to fourth memory cell arrays MCA1, MCA2, MCA3, and MCA4.

In FIG. 22, an overlap region for the first to fourth memory cell arrays MCA1, MCA2, MCA3, and MCA4 is indicated as a cell overlap region C_OVR. For example, the first page buffer circuit RGBUF1, a first row decoder XDEC1, and a first voltage generator VG1 may overlap the first memory cell array MCA1. The second page buffer circuit PGBUF2, the second row decoder XDEC2, and the second voltage generator VG2 may overlap the second memory cell array MCA2. The third page buffer circuit PGBUF3, the third row decoder XDEC3, and the third voltage generator VG3 may overlap the third memory cell array MCA3. The fourth page buffer circuit PGBUF4, the fourth row decoder XDEC4, and the fourth voltage generator VG4 may overlap the fourth memory cell array MCA4.

For example, a first node ND_A of the first row decoder XDEC1 and a second node ND_B of the second decoder XDEC2 may be connected to each other through a conductive line 225 that extends in the second direction HD2. In some embodiments, a third node ND C of the third row decoder XDEC3 and a fourth node ND D of the fourth decoder XDEC4 may be connected to each other through a conductive line 226 that extends in the second direction HD2. Alternatively or additionally, the conductive lines 225 and 226 may be implemented with linear bonding pads. In some embodiments, at least one of the conductive lines 225 and 226 may be implemented with an upper linear bonding pad. For example, at least one of the conductive lines 225 and 226 may be implemented with a lower linear bonding pad. As another example, at least one of the conductive lines 225 and 226 may be implemented with an upper linear bonding pad and a lower linear bonding pad.

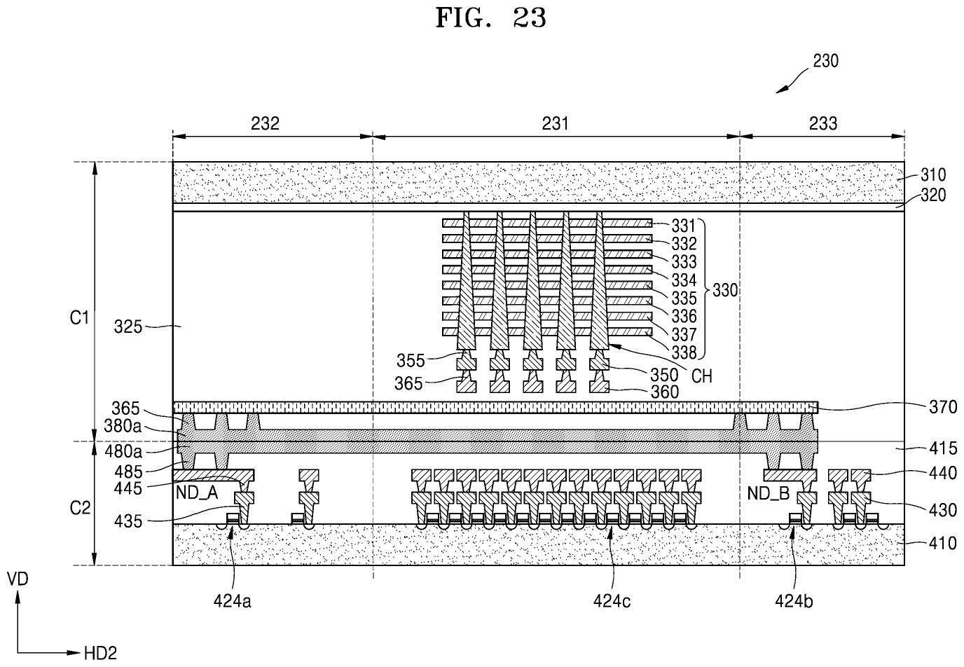

FIG. 23 is a cross-sectional view illustrating a memory device 230 according to an embodiment. The memory device 230 may correspond to an example of the memory device 220 of FIG. 22.

Referring to FIG. 23, the memory device 230 may correspond to a modified example of the memory device 70 of FIG. 7, and a redundant description thereof is omitted. The memory device 230 may be divided into first, second, and third regions 231, 232, and 233. In the first region 231, the first semiconductor chip C1 may include a plurality of channel structures CH, and the second semiconductor chip C2 may include circuit elements 424c that overlap the plurality of channel structures CH. In the second region 232, the second semiconductor chip C2 may include a circuit element 424a, and one end of the circuit element 424a may correspond to the first node ND_A. In the third region 233, the second semiconductor chip C2 may include a circuit element 424b, and one end of the circuit element 424b may correspond to the second node ND_B.

The first semiconductor chip C1 may include a second metal layer 360 and an upper bonding pad 380a that cross the first to third regions 231, 232 and 233. In this case, the second metal layer 360 may be implemented with a linear metal pattern extending in the second direction HD2. The second semiconductor chip C2 may include a lower bonding pad 480a that crosses the first to third regions 231, 232, and 233. The first node ND_A of the second region 232 may be electrically connected to the second node ND_B of the third region 233 through the first metal layer 430, the second metal layer 440, the lower bonding pad 480a, the upper bonding pad 380a, and the second metal layer 360. However, embodiments are not limited thereto. In some embodiments, the first node ND_A of the second region 232 may be electrically connected to the second node ND_B of the third region 233 through the first metal layer 430, the second metal layer 440, the lower bonding pad 480a, and the upper bonding pad 380a.

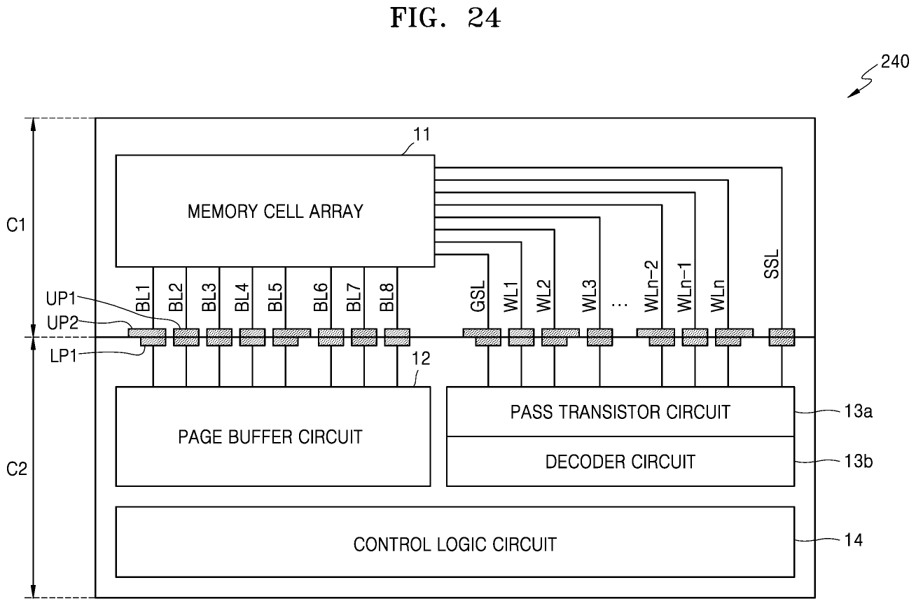

FIG. 24 illustrates a memory device 240 according to an embodiment.

Referring to FIG. 24, the memory device 240 may correspond to a modified example of the memory device 50 of FIG. 5, and a redundant description thereof is omitted. The first semiconductor chip C1 of the memory device 240 may include upper bonding pads including first upper bonding pads UP1 and second upper bonding pads UP2, and the size and/or pitch of each of the second upper bonding pads UP2 may be greater than the size and/or pitch of each of the first upper bonding pads UP1. The second semiconductor chip C2 of the memory device 240 may include a plurality of lower bonding pads including the first lower bonding pads LP1. The size and/or pitch of each of the first lower bonding pads LP1 may be substantially the same as the size and/or pitch of each of the first upper bonding pads UP1. However, embodiments are not limited thereto.

Bit lines BL1 to BL8 may be connected to the page buffer circuit 12 through first upper bonding pads UP1 and first lower bonding pads LP1 corresponding to the first upper bonding pads UP1, or second upper bonding pads UP2 and first lower bonding pads LP1 corresponding to the second upper bonding pads UP2. In this way, the size of some upper bonding pads may be greater than the size of lower bonding pads connected to the upper bonding pads. For example, each of the bit lines BL1 and BL5 may be connected to the page buffer circuit 12 through a second upper bonding pad UP2 and a first lower bonding pad LP1 corresponding to the second upper bonding pad UP2, and each of the bit lines BL2 to BL4 and BL6 to BL8 may be connected to the page buffer circuit 12 through the first upper bonding pad UP1 and the first lower bonding pad LP1 corresponding to the first upper bonding pad UP1.

In some embodiments, the first semiconductor chip C1 may include first upper bonding pads UP1, and the second semiconductor chip C2 may include first lower bonding pads LP1 and second lower bonding pads (e.g., LP2 of FIG. 10). In this case, the bit lines BL1 to BL8 may be connected to the page buffer circuit 12 through first upper bonding pads UP1 and first lower bonding pads LP1 corresponding to the first upper bonding pads UP1, or the first upper bonding pads UP1 and second lower bonding pads LP2 corresponding to the first upper bonding pads UP1. In this way, the size of some lower bonding pads may be greater than the size of upper bonding pads connected to the lower bonding pads. For example, each of the bit lines BL1 and BL5 may be connected to the page buffer circuit 12 through a first upper bonding pad UP1 and a second lower bonding pad LP2 corresponding to the first upper bonding pad UP1, and each of the bit lines BL2 to BL4 and BL6 to BL8 may be connected to the page buffer circuit 12 through the first upper bonding pad UP1 and the first lower bonding pad LP1 corresponding to the first upper bonding pad UP1.

In some embodiments, the first semiconductor chip C1 may include first upper bonding pads UP1 and second upper bonding pads UP2, and the second semiconductor chip C2 may include first lower bonding pads LP1 and second lower bonding pads (e.g., LP2 of FIG. 10). In this case, the bit lines BL1 to BL8 may be connected to the page buffer circuit 12 through first upper bonding pads UP1 and first lower bonding pads LP1 corresponding to the first upper bonding pads UP1, or the second upper bonding pads UP2 and second lower bonding pads LP2 corresponding to the second upper bonding pads UP2. In this way, the sizes of bonding pads connected to each other may be substantially the same. For example, each of the bit lines BL1 and BL5 may be connected to the page buffer circuit 12 through a second upper bonding pad UP2 and a second lower bonding pad LP2 corresponding to the second upper bonding pad UP2, and each of the bit lines BL2 to BL4 and BL6 to BL8 may be connected to the page buffer circuit 12 through the first upper bonding pad UP1 and the first lower bonding pad LP1 corresponding to the first upper bonding pad UP1.

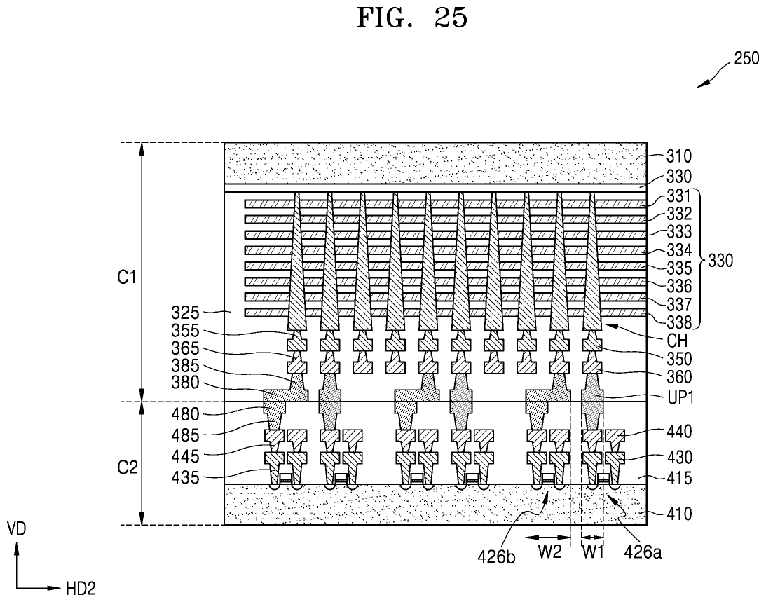

FIG. 25 is a cross-sectional view illustrating a memory device 250 according to an embodiment. The memory device 250 may correspond to an example of the memory device 240 of FIG. 24.

Referring to FIG. 25, the memory device 250 may correspond to a modified example of the memory device 70 of FIG. 7, and a redundant description thereof is omitted. Upper bonding pads 380 of a first semiconductor chip C1 may include first upper bonding pads UP1 and second upper bonding pads UP2. For example, each of the first upper bonding pads UP1 may have a first width W1 in a second direction HD2, and each of the second upper bonding pads UP2 may have a second width W2 in the second direction HD2. Each of the upper bonding pads 480 of the second semiconductor chip C2 may have the first width W1 in the second direction HD2.

The second semiconductor chip C2 may include circuit elements 426a and 426b. A first channel structure of the channel structures CH of the first semiconductor chip C1 may be connected to the circuit element 426a through the first upper bonding pad UP1 and the lower bonding pad 480, and a second channel structure of the channel structures CH of the first semiconductor chip C1 may be connected to the circuit element 426b through the second upper bonding pad UP2 and the lower bonding pad 480. For example, the circuit elements 426a and 426b may be included in a page buffer circuit (e.g., 12 of FIG. 1). In this way, circuit elements included in the page buffer circuit may be connected to channel structures corresponding to the circuit elements through upper bonding pads or lower bonding pads having different widths.

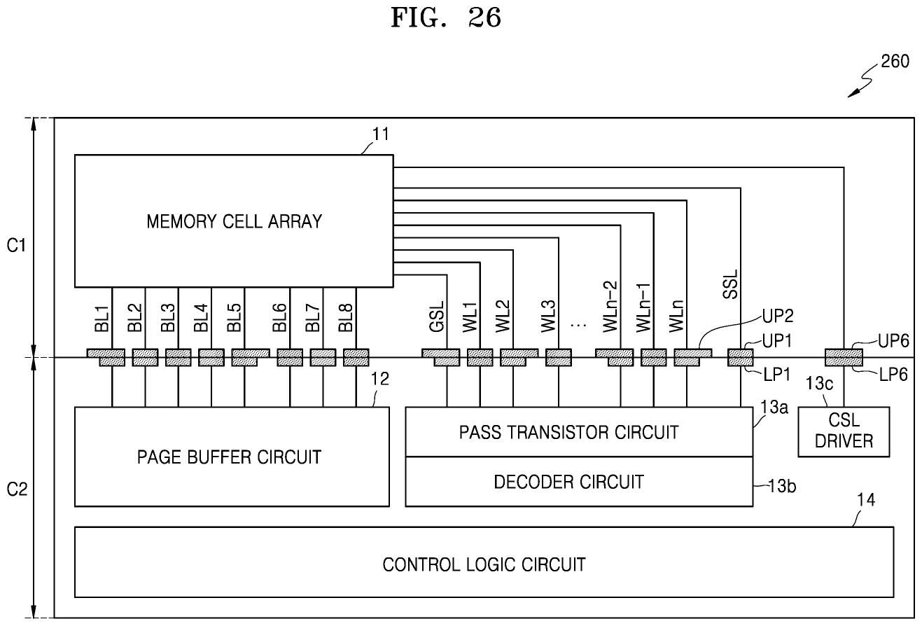

FIG. 26 illustrates a memory device 260 according to an embodiment.

Referring to FIG. 26, the memory device 260 may correspond to a modified example of the memory device 50 of FIG. 5, and a redundant description thereof is omitted. The first semiconductor chip C1 of the memory device 260 may include a plurality of upper bonding pads including first upper bonding pads UP1, second upper bonding pads UP2, and a sixth upper bonding pad UP6. The size and/or pitch of each of the second upper bonding pads UP2 may be greater than the size and/or pitch of each of the first upper bonding pads UP1, and the size and/or pitch of the sixth upper bonding pad UP6 may be greater than the size and/or pitch of each of the first upper bonding pads UP1. For example, the size and/or pitch of the sixth upper bonding pad UP6 may be greater than the size and/or pitch of each of the second upper bonding pads UP2. However, embodiments are not limited thereto. The second semiconductor chip C2 of the memory device 260 may include a plurality of lower bonding pads including the first lower bonding pads LP1 and the sixth lower bonding pad LP6. The size and/or pitch of the sixth lower bonding pad LP6 may be greater than the size and/or pitch of each of the first lower bonding pads LP1.

The memory cell array 11 of the first semiconductor chip C1 may be connected to the common source line CSL, and the second semiconductor chip C2 may further include a common source line driver 13c. The common source line CSL may be connected to the common source line driver 13c through the sixth upper bonding pad UP6 and the sixth lower bonding pad LP6. Thus, a common source line voltage generated by the common source line driver 13c may be provided to the memory cell array 11.

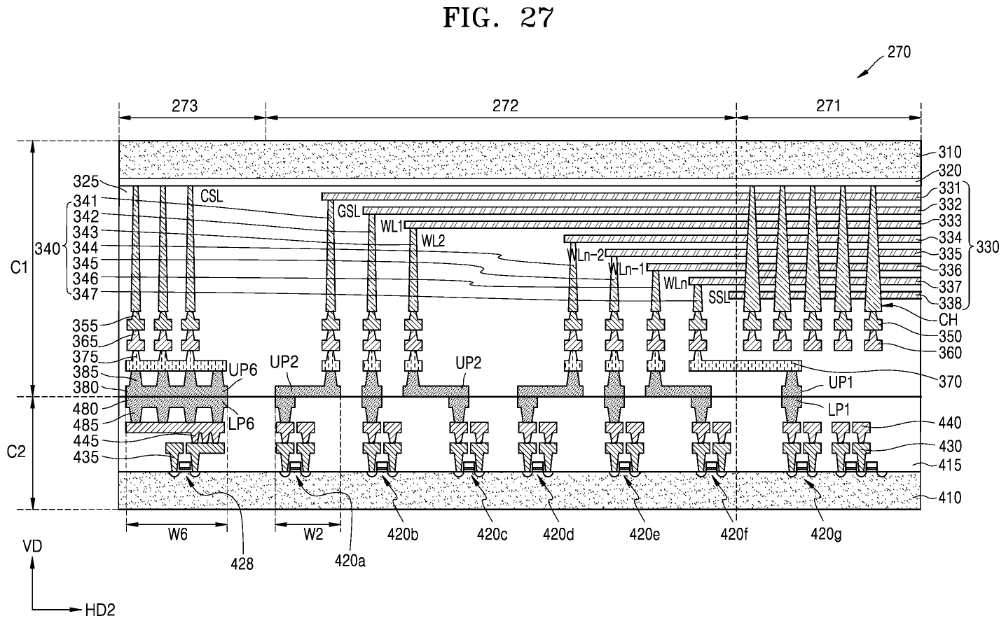

FIG. 27 is a cross-sectional view illustrating a memory device 270 according to an embodiment. The memory device 270 may correspond to an example of the memory device 260 of FIG. 26.

Referring to FIG. 27, the memory device 270 may correspond to a modified example of the memory device 70 of FIG. 7, and a redundant description thereof is omitted. Upper bonding pads 380 of a first semiconductor chip C1 may include first upper bonding pads UP1, second upper bonding pads UP2, and a sixth upper bonding pad UP6. For example, each of the second upper bonding pads UP2 may have a second width W2 in a second direction HD2, and the sixth upper bonding pad UP6 may have a sixth width W6 in a second direction HD2. Lower bonding pads 480 of a second semiconductor chip C2 may include first lower bonding pads LP1 and a sixth lower bonding pad LP6. As another example, the fifth lower bonding pad LP6 may have a sixth width W6 in the second direction HD2.

The memory device 260 may be divided into first, second, and third regions 271, 272, and 273. In the first region 271, the first semiconductor chip C1 may include a plurality of channel structures CH extending in a vertical direction VD. In the second region 272, the first semiconductor chip C1 may include a plurality of cell contact plugs 340 extending in the vertical direction VD. In the third region 273, the first semiconductor chip C1 may include a plurality of contact plugs 390 connected to the common source line 320. The common source line 320 may be connected to the plurality of contact plugs 390, the first metal layer 350, the second metal layer 360, the third metal layer 370, and the sixth upper bonding pad 380. The first metal layer 350 may be connected to the plurality of cell contact plugs 390 through the first metal contact 355, the second metal layer 360 may be connected to the first metal layer 350 through the second metal contact 365, and the third metal layer 370 may be connected to the second metal layer 360 through the third metal contact 375. The sixth upper bonding pad 380 may be connected to the third metal layer 370 through an upper bonding pad or an upper bonding metal 385.

In the third region 273, the second semiconductor chip C2 may include a circuit element 428 and a sixth lower bonding pad LP6. The circuit element 428 may be connected to the common source line CSL through the first metal layer 430, the second metal layer 440, the sixth lower bonding pad LP6, the sixth upper bonding pad UP6, the third metal layer 370, the second metal layer 360, the first metal layer 350, and the contact plug 390. For example, the circuit element 428 may be included in the common source line driver 13c. As another example, the second metal layer 440 connected to the circuit element 428 may include a linear metal pattern extending in the second direction HD2.

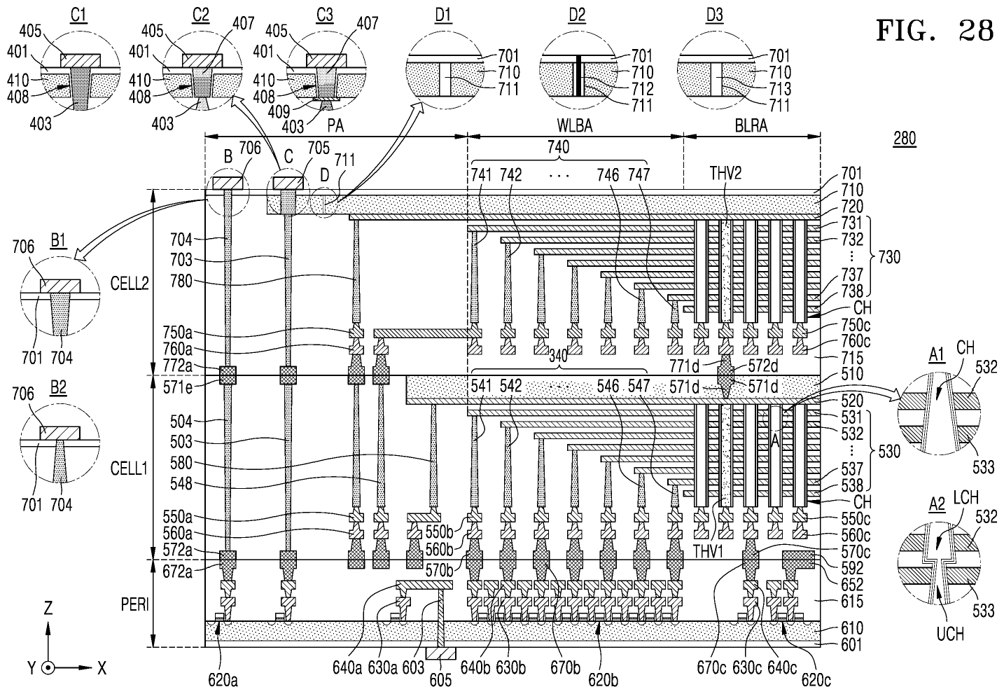

FIG. 28 is a view illustrating a memory device 280 according to some embodiments of the present disclosure.

Referring to FIG. 28, the memory device 280 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. As another example, in a case in which the bonding metal patterns are formed of copper (Cu), the bonding method may be a Cu-Cu bonding method. Alternatively or additionally, the bonding metal patterns may be formed of aluminum (Al) or tungsten (W).

The memory device 280 may include the at least one upper chip including the cell region. For example, as illustrated in FIG. 28, the memory device 280 may include two upper chips. However, the number of the upper chips is not limited thereto. In the case in which the memory device 280 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 280. The first upper chip may be turned over and then may be connected to the lower chip by the bonding method, and the second upper chip may also be turned over and then may be connected to the first upper chip by the bonding method. Hereinafter, upper and lower portions of each of the first and second upper chips are defined based on before each of the first and second upper chips is turned over. That is, an upper portion of the lower chip may mean an upper portion defined based on a +Z-axis direction, and the upper portion of each of the first and second upper chips may mean an upper portion defined based on a −Z-axis direction in FIG. 28. However, embodiments of the present disclosure are not limited thereto. In some embodiments, one of the first upper chip and the second upper chip may be turned over and then may be connected to a corresponding chip by the bonding method.

Each of the peripheral circuit region PERI and the first and second cell regions CELL1 and CELL2 of the memory device 280 may include an external pad bonding region PA, a word line bonding region WLBA, and a bit line bonding region BLRA.

The peripheral circuit region PERI may include a first substrate 610 and a plurality of circuit elements 620a, 620b and 620c formed on the first substrate 610. An interlayer insulating layer 615 including one or more insulating layers may be provided on the plurality of circuit elements 620a, 620b and 620c, and a plurality of metal lines electrically connected to the plurality of circuit elements 620a, 620b and 620c may be provided in the interlayer insulating layer 615. For example, the plurality of metal lines may include first metal lines 630a, 630b and 630c connected to the plurality of circuit elements 620a, 620b and 620c, and second metal lines 640a, 640b and 640c formed on the first metal lines 630a, 630b and 630c. The plurality of metal lines may be formed of at least one of various conductive materials. As another example, the first metal lines 630a, 630b and 630c may be formed of tungsten having a relatively high electrical resistivity, and the second metal lines 640a, 640b and 640c may be formed of copper having a relatively low electrical resistivity.

The first metal lines 630a, 630b and 630c and the second metal lines 640a, 640b and 640c are illustrated and described in the present embodiments. However, embodiments of the present disclosure are not limited thereto. In some embodiments, at least one or more additional metal lines may further be formed on the second metal lines 640a, 640b and 640c. In this case, the second metal lines 640a, 640b and 640c may be formed of aluminum, and at least some of the additional metal lines formed on the second metal lines 640a, 640b and 640c may be formed of copper having an electrical resistivity lower than that of aluminum of the second metal lines 640a, 640b and 640c.

The interlayer insulating layer 615 may be disposed on the first substrate 610 and may include an insulating material, such as silicon oxide and/or silicon nitride.

Each of the first and second cell regions CELL1 and CELL2 may include at least one memory block. The first cell region CELL1 may include a second substrate 510 and a common source line 520. A plurality of word lines 530 (e.g., 531 to 538) may be stacked on the second substrate 510 in a direction (e.g., the Z-axis direction) perpendicular to a top surface of the second substrate 510. String selection lines and a ground selection line may be disposed on and under the word lines 530, and the plurality of word lines 530 may be disposed between the string selection lines and the ground selection line. Alternatively or additionally, the second cell region CELL2 may include a third substrate 710 and a common source line 720, and a plurality of word lines 730 (e.g., 731 to 738) may be stacked on the third substrate 710 in a direction (e.g., the Z-axis direction) perpendicular to a top surface of the third substrate 710. Each of the second substrate 510 and the third substrate 710 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some embodiments, as illustrated in a region ‘A1’, the channel structure CH may be provided in the bit line bonding region BLRA and may extend in the direction perpendicular to the top surface of the second substrate 510 to penetrate the word lines 530, the string selection lines, and the ground selection line. The channel structure CH may include a data storage layer, a channel layer, and a filling insulation layer. The channel layer may be electrically connected to a first metal line 550c and a second metal line 560c in the bit line bonding region BLRA. For example, the second metal line 560c may be a bit line and may be connected to the channel structure CH through the first metal line 550c. The bit line 560c may extend in a first direction (e.g., a Y-axis direction) parallel to the top surface of the second substrate 510.

In some embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 510 to penetrate the common source line 520 and lower word lines 531 and 532. The lower channel LCH may include a data storage layer, a channel layer, and a filling insulation layer and may be connected to the upper channel UCH. The upper channel UCH may penetrate upper word lines 533 to 538. The upper channel UCH may include a data storage layer, a channel layer, and a filling insulation layer, and the channel layer of the upper channel UCH may be electrically connected to the first metal line 550c and the second metal line 560c. As a length of a channel increases, due to characteristics of manufacturing processes, it may be difficult to form a channel having a substantially uniform width. The memory device 280 according to the present embodiments may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a word line located near to a boundary between the lower channel LCH and the upper channel UCH may be a dummy word line. For example, the word lines 532 and 533 adjacent to the boundary between the lower channel LCH and the upper channel UCH may be the dummy word lines. In this case, data may not be stored in memory cells connected to the dummy word line. Alternatively or additionally, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

In some embodiments, the number of lower word lines (e.g., the lower word lines 531 and 532) penetrated by the lower channel LCH is less than the number of the upper word lines 533 to 538 penetrated by the upper channel UCH in the region ‘A2’. However, embodiments of the present disclosure are not limited thereto. In some embodiments, the number of the lower word lines penetrated by the lower channel LCH may be equal to or more than the number of the upper word lines penetrated by the upper channel UCH. Alternatively or additionally, structural features and connection relation of the channel structure CH disposed in the second cell region CELL2 may be substantially the same as those of the channel structure CH disposed in the first cell region CELL1.

In the bit line bonding region BLRA, a first through-electrode THV1 may be provided in the first cell region CELL1, and a second through-electrode THV2 may be provided in the second cell region CELL2. As illustrated in FIG. 28, the first through-electrode THV1 may penetrate the common source line 520 and the plurality of word lines 530. In some embodiments, the first through-electrode THV1 may further penetrate the second substrate 510. The first through-electrode THV1 may include a conductive material. Alternatively or additionally, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 572d and a second through-metal pattern 772d. The first through-metal pattern 572d may be formed at a bottom end of the first upper chip including the first cell region CELL1, and the second through-metal pattern 772d may be formed at a top end of the second upper chip including the second cell region CELL2. The first through-electrode THV1 may be electrically connected to the first metal line 550c and the second metal line 560c. A lower via 571d may be formed between the first through-electrode THV1 and the first through-metal pattern 572d, and an upper via 771d may be formed between the second through-electrode THV2 and the second through-metal pattern 772d. The first through-metal pattern 572d and the second through-metal pattern 772d may be connected to each other by the bonding method.

Alternatively or additionally, in the bit line bonding region BLRA, an upper metal pattern 652 may be formed in an uppermost metal layer of the peripheral circuit region PERI, and an upper metal pattern 592 having the same shape as the upper metal pattern 652 may be formed in an uppermost metal layer of the first cell region CELL1. The upper metal pattern 592 of the first cell region CELL1 and the upper metal pattern 652 of the peripheral circuit region PERI may be electrically connected to each other by the bonding method. In the bit line bonding region BLRA, the bit line 560c may be electrically connected to a page buffer included in the peripheral circuit region PERI. For example, some of the circuit elements 620c of the peripheral circuit region PERI may constitute the page buffer, and the bit line 560c may be electrically connected to the circuit elements 620c constituting the page buffer through an upper bonding metal pattern 570c of the first cell region CELL1 and an upper bonding metal pattern 670c of the peripheral circuit region PERI.

Continuing to refer to FIG. 28, in the word line bonding region WLBA, the word lines 530 of the first cell region CELL1 may extend in a second direction (e.g., an X-axis direction) parallel to the top surface of the second substrate 510 and may be connected to a plurality of cell contact plugs 540 (e.g., 541 to 547). First metal lines 550b and second metal lines 560b may be sequentially connected onto the cell contact plugs 540 connected to the word lines 530. In the word line bonding region WLBA, the cell contact plugs 540 may be connected to the peripheral circuit region PERI through upper bonding metal patterns 570b of the first cell region CELL1 and upper bonding metal patterns 670b of the peripheral circuit region PERI.

The cell contact plugs 540 may be electrically connected to a row decoder included in the peripheral circuit region PERI. For example, some of the circuit elements 620b of the peripheral circuit region PERI may constitute the row decoder, and the cell contact plugs 540 may be electrically connected to the circuit elements 620b constituting the row decoder through the upper bonding metal patterns 570b of the first cell region CELL1 and the upper bonding metal patterns 670b of the peripheral circuit region PERI. In some embodiments, an operating voltage of the circuit elements 620b constituting the row decoder may be different from an operating voltage of the circuit elements 620c constituting the page buffer. For example, the operating voltage of the circuit elements 620c constituting the page buffer may be greater than the operating voltage of the circuit elements 620b constituting the row decoder.

Alternatively or additionally, in the word line bonding region WLBA, the word lines 730 of the second cell region CELL2 may extend in the second direction (e.g., the X-axis direction) parallel to the top surface of the third substrate 710 and may be connected to a plurality of cell contact plugs 740 (e.g., 741 to 747). The cell contact plugs 740 may be connected to the peripheral circuit region PERI through an upper metal pattern of the second cell region CELL2 and lower and upper metal patterns and a cell contact plug 548 of the first cell region CELL1.

In the word line bonding region WLBA, the upper bonding metal patterns 570b may be formed in the first cell region CELL1, and the upper bonding metal patterns 670b may be formed in the peripheral circuit region PERI. The upper bonding metal patterns 570b of the first cell region CELL1 and the upper bonding metal patterns 670b of the peripheral circuit region PERI may be electrically connected to each other by the bonding method. The upper bonding metal patterns 570b and the upper bonding metal patterns 670b may be formed of aluminum, copper, tungsten, or a combination thereof.

In the external pad bonding region PA, a lower metal pattern 571e may be formed in a lower portion of the first cell region CELL1, and an upper metal pattern 772a may be formed in an upper portion of the second cell region CELL2. The lower metal pattern 571e of the first cell region CELL1 and the upper metal pattern 772a of the second cell region CELL2 may be connected to each other by the bonding method in the external pad bonding region PA. Alternatively or additionally, an upper metal pattern 572a may be formed in an upper portion of the first cell region CELL1, and an upper metal pattern 672a may be formed in an upper portion of the peripheral circuit region PERI. The upper metal pattern 572a of the first cell region CELL1 and the upper metal pattern 672a of the peripheral circuit region PERI may be connected to each other by the bonding method.

Common source line contact plugs 580 and 780 may be disposed in the external pad bonding region PA. The common source line contact plugs 580 and 780 may be formed of a conductive material such as a metal, a metal compound, and/or doped polysilicon. The common source line contact plug 580 of the first cell region CELL1 may be electrically connected to the common source line 520, and the common source line contact plug 780 of the second cell region CELL2 may be electrically connected to the common source line 720. A first metal line 550a and a second metal line 560a may be sequentially stacked on the common source line contact plug 580 of the first cell region CELL1, and a first metal line 750a and a second metal line 760a may be sequentially stacked on the common source line contact plug 780 of the second cell region CELL2.

Input/output pads 605, 705 and 706 may be disposed in the external pad bonding region PA. Continuing to refer to FIG. 28, a lower insulating layer 601 may cover a bottom surface of the first substrate 610, and a first input/output pad 605 may be formed on the lower insulating layer 601. The first input/output pad 605 may be connected to at least one of a plurality of the circuit elements 620a disposed in the peripheral circuit region PERI through a first input/output contact plug 603 and may be separated from the first substrate 610 by the lower insulating layer 601. Alternatively or additionally, a side insulating layer may be disposed between the first input/output contact plug 603 and the first substrate 610 to electrically isolate the first input/output contact plug 603 from the first substrate 610.

An upper insulating layer 701 covering a top surface of the third substrate 710 may be formed on the third substrate 710. A second input/output pad 705 and/or a third input/output pad 706 may be disposed on the upper insulating layer 701. The second input/output pad 705 may be connected to at least one of the plurality of circuit elements 620a disposed in the peripheral circuit region PERI through second input/output contact plugs 703 and 503, and the third input/output pad 706 may be connected to at least one of the plurality of circuit elements 620a disposed in the peripheral circuit region PERI through third input/output contact plugs 704 and 504.

In some embodiments, the third substrate 710 may not be disposed in a region in which the input/output contact plug is disposed. For example, as illustrated in a region 13′, the third input/output contact plug 704 may be separated from the third substrate 710 in a direction parallel to the top surface of the third substrate 710 and may penetrate an interlayer insulating layer 715 of the second cell region CELL2 so as to be connected to the third input/output pad 706. In this case, the third input/output contact plug 704 may be formed by at least one of various processes.

In some embodiments, as illustrated in a region ‘B1’, the third input/output contact plug 704 may extend in a third direction (e.g., the Z-axis direction), and a diameter of the third input/output contact plug 704 may become progressively greater toward the upper insulating layer 701. That is, a diameter of the channel structure CH described in the region ‘A1’ may become progressively less toward the upper insulating layer 701, but the diameter of the third input/output contact plug 704 may become progressively greater toward the upper insulating layer 701. For example, the third input/output contact plug 704 may be formed after the second cell region CELL2 and the first cell region CELL1 are bonded to each other by the bonding method.

In some embodiments, as illustrated in a region ‘B2’, the third input/output contact plug 704 may extend in the third direction (e.g., the Z-axis direction), and a diameter of the third input/output contact plug 704 may become progressively less toward the upper insulating layer 701. That is, like the channel structure CH, the diameter of the third input/output contact plug 704 may become progressively less toward the upper insulating layer 701. For example, the third input/output contact plug 704 may be formed together with the cell contact plugs 740 before the second cell region CELL2 and the first cell region CELL1 are bonded to each other.

In some embodiments, the input/output contact plug may overlap with the third substrate 710. For example, as illustrated in a region ‘C’, the second input/output contact plug 703 may penetrate the interlayer insulating layer 715 of the second cell region CELL2 in the third direction (e.g., the Z-axis direction) and may be electrically connected to the second input/output pad 705 through the third substrate 710. In this case, a connection structure of the second input/output contact plug 703 and the second input/output pad 705 may be realized by various methods. The present disclosure is not limited in this regard.

In some embodiments, as illustrated in a region ‘C1’, an opening 708 may be formed to penetrate the third substrate 710, and the second input/output contact plug 703 may be connected directly to the second input/output pad 705 through the opening 708 formed in the third substrate 710. In this case, as illustrated in the region ‘C1’, a diameter of the second input/output contact plug 703 may become progressively greater toward the second input/output pad 705. However, embodiments of the present disclosure are not limited thereto. In some embodiments, the diameter of the second input/output contact plug 703 may become progressively less toward the second input/output pad 705.

In some embodiments, as illustrated in a region ‘C2’, the opening 708 penetrating the third substrate 710 may be formed, and a contact 707 may be formed in the opening 708. An end of the contact 707 may be connected to the second input/output pad 705, and another end of the contact 707 may be connected to the second input/output contact plug 703. Thus, the second input/output contact plug 703 may be electrically connected to the second input/output pad 705 through the contact 707 in the opening 708. In this case, as illustrated in the region ‘C2’, a diameter of the contact 707 may become progressively greater toward the second input/output pad 705, and a diameter of the second input/output contact plug 703 may become progressively less toward the second input/output pad 705. For example, the second input/output contact plug 703 may be formed together with the cell contact plugs 740 before the second cell region CELL2 and the first cell region CELL1 are bonded to each other, and the contact 707 may be formed after the second cell region CELL2 and the first cell region CELL1 are bonded to each other.

In some embodiments illustrated in a region ‘C3’, a stopper 709 may further be formed on a bottom end of the opening 708 of the third substrate 710, as compared with the embodiments of the region ‘C2’. The stopper 709 may be a metal line formed in the same layer as the common source line 720. Alternatively or additionally, the stopper 709 may be a metal line formed in the same layer as at least one of the word lines 730. The second input/output contact plug 703 may be electrically connected to the second input/output pad 705 through the contact 707 and the stopper 709.

Like the second and third input/output contact plugs 703 and 704 of the second cell region CELL2, a diameter of each of the second and third input/output contact plugs 503 and 504 of the first cell region CELL1 may become progressively less toward the lower metal pattern 571e or may become progressively greater toward the lower metal pattern 571e.

In some embodiments, a slit 711 may be formed in the third substrate 710. For example, the slit 711 may be formed at a certain position of the external pad bonding region PA. As another example, as illustrated in a region ‘D’, the slit 711 may be located between the second input/output pad 705 and the cell contact plugs 740 when viewed in a plan view. Alternatively or additionally, the second input/output pad 705 may be located between the slit 711 and the cell contact plugs 740 when viewed in a plan view.

In some embodiments, as illustrated in a region ‘D1’, the slit 711 may be formed to penetrate the third substrate 710. For example, the slit 711 may be used to prevent the third substrate 710 from being finely cracked when the opening 708 is formed. However, embodiments of the present disclosure are not limited thereto. In some embodiments, the slit 711 may be formed to have a depth ranging from about 60% to about 70% of a thickness of the third substrate 710.

In some embodiments, as illustrated in a region ‘D2’, a conductive material 712 may be formed in the slit 711. For example, the conductive material 712 may be used to discharge a leakage current occurring in driving of the circuit elements in the external pad bonding region PA to the outside. In this case, the conductive material 712 may be connected to an external ground line.

In some embodiments, as illustrated in a region ‘D3’, an insulating material 713 may be formed in the slit 711. For example, the insulating material 713 may be used to electrically isolate the second input/output pad 705 and the second input/output contact plug 703 disposed in the external pad bonding region PA from the word line bonding region WLBA. Since the insulating material 713 is formed in the slit 711, it is possible to prevent a voltage provided through the second input/output pad 705 from affecting a metal layer disposed on the third substrate 710 in the word line bonding region WLBA.

In some embodiments, the first to third input/output pads 605, 705 and 706 may be selectively formed. For example, the memory device 280 may be realized to include only the first input/output pad 605 disposed on the first substrate 610, to include only the second input/output pad 705 disposed on the third substrate 710, or to include only the third input/output pad 706 disposed on the upper insulating layer 701.

In some embodiments, at least one of the second substrate 510 of the first cell region CELL1 or the third substrate 710 of the second cell region CELL2 may be used as a sacrificial substrate and may be completely or partially removed before or after a bonding process. An additional layer may be stacked after the removal of the substrate. For example, the second substrate 510 of the first cell region CELL1 may be removed before or after the bonding process of the peripheral circuit region PERI and the first cell region CELL1, and then, an insulating layer covering a top surface of the common source line 520 or a conductive layer for connection may be formed. Alternatively or additionally, the third substrate 710 of the second cell region CELL2 may be removed before or after the bonding process of the first cell region CELL1 and the second cell region CELL2, and then, the upper insulating layer 701 covering a top surface of the common source line 720 or a conductive layer for connection may be formed.

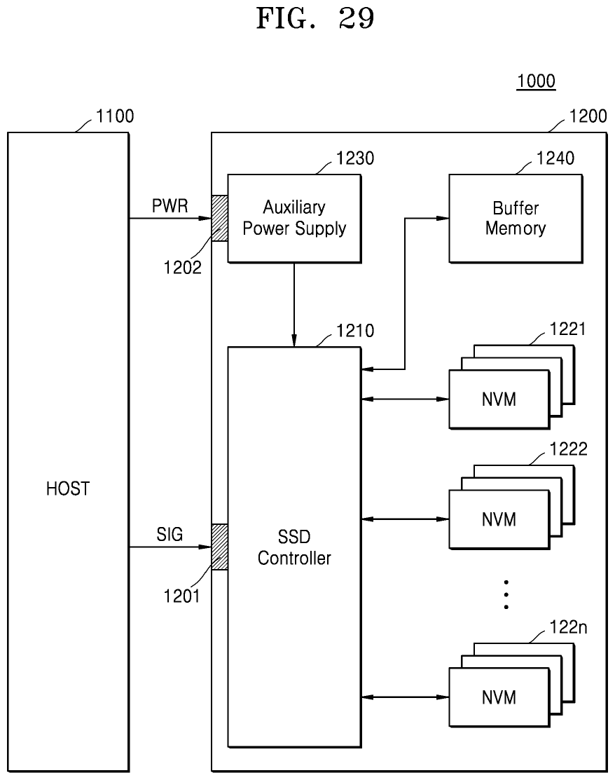

FIG. 29 is a block diagram illustrating a solid state drive (SSD) system 1000 to which a memory device according to an embodiment is applied. Referring to FIG. 29, the SSD system 1000 may include a host 1100 and an SSD 1200. The SSD 1200 may exchange a signal with the host 1100 through a signal connector and may receive power through a power connector. The SSD 1200 may include an SSD controller 1210, an auxiliary power supply 1230, and memory devices 1221, 1222, and 122n. The memory devices 1221, 1222, and 122n may be vertical stack type NAND flash memory devices. In this case, the SSD 1200 may be implemented by using embodiments described with reference to FIGS. 1 through 28.

As described above, example embodiments have been disclosed in the present disclosure. Although the embodiments have been described using certain terms herein, this is used for the purpose of explaining the technical idea of the present disclosure, not to be used to limit the scope of the present disclosure described in the claims. Therefore, it will be understood by those skilled in the art that various modifications and other equivalent embodiments are possible therefrom. Thus, the true technical protection scope of the present disclosure should be defined by the technical idea of the claims.

While the present disclosure has been particularly shown and described with reference to embodiments thereof, it will be understood that various changes in form and details may be made therein without departing from the spirit and scope of the following claims.

What is claimed is:

1. A non-volatile memory device comprising:
a first semiconductor chip comprising:
gate electrodes each extending in a first direction and stacked in a second direction;
channel structures extending from a first region in the second direction;
a plurality of cell contact plugs comprising a first cell contact plug, a second cell contact plug, and a third cell contact plug, each of the plurality of cell contact plugs coupled to the gate electrodes in a second region;
a linear metal pattern extending in the first direction; and
a plurality of upper bonding pads comprising a first upper bonding pad, a second upper bonding pad, and a third upper bonding pad; and
a second semiconductor chip comprising:
a plurality of lower bonding pads comprising a first lower bonding pad, a second lower bonding pad, and a third lower bonding pad;
a first peripheral circuit element overlapping the channel structures;
a second peripheral circuit element overlapping the plurality of cell contact plugs; and
a third peripheral circuit element overlapping the plurality of cell contact plugs,
wherein the first cell contact plug is coupled to the first peripheral circuit element through the linear metal pattern, the first upper bonding pad, and the first lower bonding pad,
wherein the second cell contact plug is coupled to the second peripheral circuit element through the second upper bonding pad and the second lower bonding pad,
wherein the third cell contact plug is coupled to the third peripheral circuit element through the third upper bonding pad and the third lower bonding pad, and
wherein a width in the first direction of the second upper bonding pad is different from a width in the first direction of the third upper bonding pad or a width in the first direction of the second lower bonding pad is different from a width in the first direction of the third lower bonding pad.

2. The non-volatile memory device of claim 1, wherein the width in the first direction of the second upper bonding pad is greater than a width in the first direction of the first upper bonding pad.

3. The non-volatile memory device of claim 1, wherein the width in the first direction of the second lower bonding pad is greater than a width in the first direction of the first lower bonding pad.

4. The non-volatile memory device of claim 1, wherein the first upper bonding pad and the first lower bonding pad have a first width in the first direction,
wherein the width in the first direction of the second upper bonding pad and the width in the first direction of the second lower bonding pad is a second width, and
wherein the second width is greater than the first width.

5. The non-volatile memory device of claim 1, wherein the gate electrodes comprise a string selection line, word lines, and a ground selection line,
wherein the first cell contact plug is coupled to the string selection line,
wherein the second cell contact plug is coupled to a word line of the word lines and the ground selection line, and
wherein the third cell contact plug is coupled to another word line of the word lines and the ground selection line.

6. The non-volatile memory device of claim 1, wherein the first peripheral circuit element, the second peripheral circuit element, and the third peripheral circuit element provide a row decoder.

7. The non-volatile memory device of claim 1, wherein the first semiconductor chip further comprises:
a fourth upper bonding pad disposed in the first region and coupled to a first channel structure of the channel structures; and
a fifth upper bonding pad disposed in the first region and coupled to a second channel structure of the channel structures, and
wherein the second semiconductor chip further comprises:
a fourth lower bonding pad coupled to the fourth upper bonding pad;
a fifth lower bonding pad coupled to the fifth upper bonding pad;
a fourth peripheral circuit element coupled to the fourth upper bonding pad; and
a fifth peripheral circuit element coupled to the fifth lower bonding pad, and
wherein a width in the first direction of the fourth upper bonding pad is different from a width in the first direction of the fifth upper bonding pad, or a width in the first direction of the fourth lower bonding pad is different from a width in the first direction of the fifth lower bonding pad.

8. The non-volatile memory device of claim 7, wherein the fourth peripheral circuit element and the fifth peripheral circuit element provide a page buffer circuit.

9. The non-volatile memory device of claim 1, wherein the first semiconductor chip further comprises:
a common source line extending in the first direction;
at least one contact plug commonly coupled to the common source line; and
a fourth upper bonding pad coupled to the at least one contact plug, and
wherein the second semiconductor chip further comprises:
a fourth lower bonding pad coupled to the fourth upper bonding pad; and
a fourth peripheral circuit element coupled to the fourth lower bonding pad, and
wherein the first upper bonding pad has a first width in the first direction, and
wherein at least one of the fourth upper bonding pad and the fourth lower bonding pad has a second width in the first direction greater than the first width.

10. The non-volatile memory device of claim 9, wherein the fourth peripheral circuit element provides a common source line driver.

11. A non-volatile memory device comprising:
a first semiconductor chip comprising:
gate electrodes each extending in a first direction and stacked in a second direction;
channel structures extending from a first region in the second direction;
cell contact plugs each coupled to the gate electrodes in a second region;
a first upper bonding pad; and
a second upper bonding pad; and
a second semiconductor chip comprising:
a first lower bonding pad;
a second lower bonding pad;
a first peripheral circuit element overlapping the channel structures; and
a second peripheral circuit element overlapping the cell contact plugs,
wherein a first cell contact plug of the cell contact plugs is coupled to the first peripheral circuit element through the first upper bonding pad and the first lower bonding pad,
wherein a second cell contact plug of the cell contact plugs is coupled to the second peripheral circuit element through the second upper bonding pad and the second lower bonding pad, and
wherein the second upper bonding pad and the second lower bonding pad have a first width in the first direction, and
wherein at least one of the first upper bonding pad and the first lower bonding pad has a second width in the first direction greater than the first width.

12. The non-volatile memory device of claim 11, wherein the gate electrodes comprises a string selection line, word lines, and a ground selection line,
wherein the first cell contact plug is coupled to the string selection line, and
wherein the second cell contact plug is in the first direction to a word line of the word lines and the ground selection line.

13. The non-volatile memory device of claim 11, wherein the first semiconductor chip further comprises a third upper bonding pad having the second width in the first direction,
wherein the second semiconductor chip further comprises a third lower bonding pad and a third peripheral circuit element overlapping the cell contact plugs, and
wherein a third cell contact plug of the cell contact plugs is coupled to the third peripheral circuit element through the third upper bonding pad and the third lower bonding pad.

14. The non-volatile memory device of claim 11, wherein the first semiconductor chip further comprises:
a third upper bonding pad disposed in the first region and coupled to a first channel structure of the channel structures; and
a fourth upper bonding pad disposed in the first region and coupled to a second channel structure of the channel structures, and
wherein the second semiconductor chip further comprises:
a third lower bonding pad coupled to the third upper bonding pad;
a fourth lower bonding pad coupled to the fourth upper bonding pad;
a third peripheral circuit element coupled to the third upper bonding pad; and
a fourth peripheral circuit element coupled to the fourth lower bonding pad, and
wherein a width in the first direction of the third upper bonding pad is different from a width in the first direction of the fourth upper bonding pad, or a width in the first direction of the third lower bonding pad is different from a width in the first direction of the fourth lower bonding pad.

15. The non-volatile memory device of claim 11, wherein the first semiconductor chip further comprises:
a common source line extending in the first direction;
at least one contact plug commonly coupled to the common source line; and
a third upper bonding pad coupled to the at least one contact plug, and
wherein the second semiconductor chip further comprises:
a third lower bonding pad coupled to the third upper bonding pad; and
a third peripheral circuit element coupled to the third lower bonding pad, and
wherein the first upper bonding pad has a third width in the first direction, and
wherein at least one of the third upper bonding pad and the third lower bonding pad has a fourth width in the first direction greater than the third width.

16. A non-volatile memory device comprising:
a first semiconductor chip comprising a memory cell array, a first upper bonding pad having a first width in a first direction, and a second upper bonding pad having a second width greater in the first direction than the first width; and
a second semiconductor chip comprising a first lower bonding pad and coupled to the first semiconductor chip in a vertical direction through the first upper bonding pad and the first lower bonding pad,
wherein the second semiconductor chip further comprises:
a second lower bonding pad coupled to the second upper bonding pad;
a third lower bonding pad coupled to the second upper bonding pad;
a first peripheral circuit element coupled to the second lower bonding pad; and
a second peripheral circuit element coupled to the third lower bonding pad, and
wherein the first peripheral circuit element is coupled to the second peripheral circuit element through the second lower bonding pad, the second upper bonding pad, and the third lower bonding pad.

17. The non-volatile memory device of claim 16, wherein the second semiconductor chip further comprises:
a fourth lower bonding pad coupled to the second upper bonding pad;
a linear metal pattern coupled to the fourth lower bonding pad and extending in the first direction; and
a third peripheral circuit element coupled to the linear metal pattern, and
wherein the first peripheral circuit element is coupled to the third peripheral circuit element through the second lower bonding pad, the second upper bonding pad, the fourth lower bonding pad, and the linear metal pattern.

18. The non-volatile memory device of claim 16, wherein the second semiconductor chip further comprises:
a fourth lower bonding pad having a third width in the first direction greater than the first width; and
a third peripheral circuit element and a fourth peripheral circuit element coupled to the fourth lower bonding pad.

19. The non-volatile memory device of claim 18, wherein the first semiconductor chip further comprises a third upper bonding pad having the third width in the first direction, and
wherein the third peripheral circuit element is coupled to the fourth peripheral circuit element through the fourth lower bonding pad and the third upper bonding pad.

20. The non-volatile memory device of claim 16, wherein the memory cell array comprises a first memory cell array and a second memory cell array,
wherein the first semiconductor chip further comprises a third upper bonding pad having a third width in the first direction greater than the second width,
wherein the second semiconductor chip further comprises:
a first peripheral circuit corresponding to the first memory cell array;
a second peripheral circuit corresponding to the second memory cell array; and
a fourth lower bonding pad commonly coupled to the first peripheral circuit and the second peripheral circuit, and
wherein the first peripheral circuit is coupled to the second peripheral circuit through the fourth lower bonding pad and the third upper bonding pad.
